(19) United States
(12) Patent Application Publication
(10) Pub. No.: US 2023/0389346 A1
(43) Pub. Date: Nov. 30, 2023

(54) QUANTUM DEVICES AND METHODS FOR MAKING THE SAME

(71) Applicant: National Yang Ming Chiao Tung University, Hsinchu City (TW)

(72) Inventors: Pei-Wen LI, Taipei City (TW); I-Hsiang WANG, Tainan City (TW); Po-Yu HONG, New Taipei City (TW)

(21) Appl. No.: 17/834,966

(22) Filed: Jun. 8, 2022

Related U.S. Application Data
(60) Provisional application No. 63/345,343, filed on May 24, 2022.

(51) Int. Cl. H01L 51/50; H01L 51/05; C01B 33/12; C01G 17/00; B82Y 30/00; B82Y 10/00

(52) U.S. Cl. CPC H01L 51/502; H01L 51/0512; C01B 33/12; C01G 17/00; B82Y 30/00; B82Y 10/00; C01P 2004/64

(57) ABSTRACT

The present disclosure relates to structures and methods of quantum devices. A quantum device comprises a substrate with an insulation surface and at least one quantum component disposed on the insulation surface of the substrate. The at least one quantum component may comprise multiple plateau members and at least one quantum dot. Each plateau member is disposed at an angle against an adjacent plateau member. Each quantum dot is formed within an insulation body and disposed at an included-angle location of two adjacent plateau members of the multiple plateau members. In addition, the at least one quantum component is operable under high temperature, such as above 4 K.

### RELATED APPLICATION

This application claims the benefit of the provisional application 63/346,343 filed on May 27, 2022, titled “QUANTUM DOT AND PREPARATION METHOD,” which is incorporated herein by reference at its entirety.

In addition, the U.S. Pat. No. 11,227,765, filed on Jul. 17, 2020, titled “SELF-ORGANIZED QUANTUM DOT MANUFACTURING METHOD AND QUANTUM DOT SEMICONDUCTOR STRUCTURE” and U.S. Pat. No. 9,299,796 filed on Feb. 11, 2015, titled “METHOD FOR MANUFACTURING GATE STACK STRUCTURE IN lNSTAMETAL-OXIDE-SEMICONDUCTOR FIELD-EFFECT-TRANSISTOR” are incorporated herein by reference at their entireties.

### BACKGROUND OF THE INVENTION

### Field of the Invention

The present invention relates to structure of and method of making quantum devices comprising quantum dots; more particularly, to quantum devices operable at a high temperature.

### Description of Related Art

Quantum computing is the processing of information that is represented by special quantum states. The power of quantum computing is based on fundamental principles of quantum mechanics, such as quantum superposition and quantum entanglement. Since the inception of quantum computing in the early 1980, extensive research on photons, ion traps, superconducting circuits, and semiconductor quantum dots (QDs) has resulted in spectacular advances in quantum-bit (qubit) technologies potentially facilitating a vast landscape of applications. Although impressive achievements have been made using superconducting qubits, they can only be made with very limited number, such as 50 qubits, and be operated at extremely low temperature, such as mK. Thus, there is also a need to provide a quantum device with scalable quantum dots (QDs), which is operable under high temperature.

### SUMMARY

The present disclosure relates to structures and methods of quantum devices. A quantum device comprises a substrate with an insulation surface and at least one quantum component disposed on the insulation surface of the substrate. The at least one quantum component may comprise multiple plateau members and at least one quantum dot. Each plateau member is disposed at an angle against an adjacent plateau member. Each quantum dot is formed within an insulation body and disposed at an included-angle location of two adjacent plateau members of the multiple plateau members. In addition, the at least one quantum component is operable under high temperature, such as above 4 K. The properties of a quantum dot may be determined at least by its material, size, shape, strain, purity, crystallinity, and inter-quantum dot spacing (for a quantum component including two or more quantum dots). To be operable at such a high temperature, each quantum dot may have one or more of the following features: a diameter less than or equal to two times of an exciton Bohr radius of the material of the quantum dot, approximately a spherical shape, and single crystallinity. In one embodiment, each plateau member and each quantum dot may comprise semiconductor materials. Specifically, in one embodiment, each plateau member comprises silicon, each quantum dot comprises germanium, and each insulation body comprises silicon oxide. In the embodiment of germanium quantum dot (QD), a diameter of such a quantum dot is less than approximately 25 nm. In addition, each quantum dot may have a chemical purity of germanium at approximately 100% and/or a single crystallinity. For a quantum device including two or more quantum dots, a distance between each two adjacent quantum dots may be less than approximately 20 nm.

A method for making the invented quantum device described above comprises step (a) forming N plateau members on a substrate with an insulation surface wherein N is an integer larger than 1; step (b) forming a first insulating layer on the N multiple plateau members; and step (c) forming N−1 quantum dots. At step (a), each two adjacent plateau members of the N multiple plateau members form an angle. At step (c), each quantum dot is formed within an insulation body and disposed at an included-angle location of each two adjacent plateau members. The step (c) may further comprise step (c1) forming a semiconductor-alloyed layer on the first insulating layer; step (c2) forming N−1 semiconductor-alloyed islands by etching; and step (c3) oxidizing each semiconductor-alloyed island to form a quantum dot within an insulation body. At step (c2), each semiconductor-alloyed island is disposed, in a self-aligned process, at an included-angle location of each two adjacent plateau members. In one embodiment, thermal oxidation is used to oxidize each semiconductor-alloyed island. In another embodiment, other oxidation methods may be used. The method may further comprise step (d) forming N−1 plunger gates. At step (d), each plunger gate is disposed, in a self-aligned process, adjacent to a quantum dot and between the corresponding two adjacent plateau members.

In one embodiment, a quantum device includes a substrate with an insulation surface and at least one quantum component. The at least one quantum component may be a single electron transistor (SET), a single hole transistor (SHT), a single electron transistor invertor (SETI), a single hole transistor inverter (SHTI), a qubit, and a double qubit. For example, an SET or a SHT may contain two plateau members and one quantum dot. An SETI or SHT may contain three plateau members and two quantum dots. A qubit may contain three plateau members and two quantum dots. A double qubit may contain four plateau members and three quantum dots. These quantum components may be combined by sharing a plateau member. For example, a SET may be combined with a qubit to measure signals of the qubit. This combination may contain four plateau members and three quantum dots because one plateau member is shared by the SET and the qubit.

The structure of and method for making the quantum devices disclosed in this application have one or more of the following advantages. (1) The quantum devices are operable at a high temperature, such as 4K and above. (2) The quantum dot is isotropic and symmetric with respect to quantum confinement effect when it is in approximately a spherical shape. (3) The location of the quantum dot may be precisely tuned. (4) The number of quantum dots formed in a quantum device is scalable and unlimited. (5) The diameter (size) of quantum dots is tunable. (6) The distance between two adjacent quantum dots is tunable. (7) Plunger gates and barrier gates may be formed by a self-aligned process. (8) The quantum device may be manufactured by CMOS compatible fabrication approach. (9) Each quantum component is independently addressable and electrically tunable. (10) The quantum dots in a quantum device may be reconfigurable into different types of quantum components.

### BRIEF DESCRIPTION OF THE DRAWINGS

FIG. 1 is a perspective view of a quantum device including two plateau members and one quantum dot in accordance to an embodiment of the present invention.

FIG. 2A is a perspective view of a quantum device comprising an SET or SHT quantum component in accordance to an embodiment of the present invention.

FIG. 2B is a top view of a quantum device comprising an SET or SHT quantum component in accordance to an embodiment of the present invention.

FIG. 2C is an equivalent circuit of an SET or SHT quantum component in accordance to an embodiment of the present invention.

FIG. 2D is a band diagram of a quantum device in accordance to an embodiment of the present invention.

FIGS. 3A-3E are schematic views of SET operation by manipulating V_{DS}.

FIGS. 4A-4E are schematic views of SET operation by manipulating V_{G}.

FIG. 5A is an experimental characteristics of I_{D}-V_{D}-V_{G} curves of Ge quantum dot SHT measured at temperature of 77 K.

FIG. 5B is a Coulomb stability diagram of Ge quantum dot SHT contour plot measured at temperature of 77 K.

FIG. 5C is a schematic diagram comparing I_{D}-V_{G} curves of Ge quantum dot (10 nm) SHTs measured at 77-140 K.

FIG. 6 is a perspective view of a quantum device comprising an SETI or SHTI quantum component in accordance to an embodiment of the present invention.

FIG. 7A is a perspective view of a quantum device comprising an SETI or an SHTI quantum component in accordance to an embodiment of the present invention.

FIG. 7B is a top view of a quantum device comprising an SETI or an SHTI in accordance to an embodiment of the present invention.

FIG. 7C is an equivalent circuit of an SETI or an SHTI quantum component in accordance to an embodiment of the present invention.

FIG. 8A is a perspective view of a quantum device comprising a qubit quantum component in accordance to an embodiment of the present invention.

FIG. 8B is a top view of a quantum device comprising a qubit quantum component in accordance to an embodiment of the present invention.

FIG. 8C is an equivalent circuit of a qubit quantum component in accordance to an embodiment of the present invention.

FIG. 9 is a perspective view of a quantum device comprising a double qubit quantum component in accordance to an embodiment of the present invention.

FIG. 10A is a perspective view of a quantum device comprising a double qubit quantum component in accordance to an embodiment of the present invention.

FIG. 10B is a top view of a quantum device comprising a double qubit quantum component in accordance to an embodiment of the present invention.

FIG. 11 is a perspective view of a quantum device with eight plateau members and eight quantum dots in accordance to an embodiment of the present invention.

FIG. 12A is a perspective view of a quantum device with eight plateau members and eight quantum dots in accordance to an embodiment of the present invention.

FIG. 12B is a top view of a quantum device with eight plateau members and eight quantum dots in accordance to an embodiment of the present invention.

FIG. 12C is an equivalent circuit of four quantum components, two SETs/SHTs and two double qubits, in accordance to an embodiment of the present invention.

FIGS. 13A-13G are perspective views of manufacturing a quantum device with two SETs/SHTs in accordance of an embodiment of the present invention.

FIGS. 14A-14F are cross sectional views of manufacturing a qubit and an SET/SHT in accordance of an embodiment of the present invention

### DETAILED DESCRIPTION OF PREFERRED EMBODIMENTS

The terminology used in the description presented below is intended to be interpreted in its broadest reasonable manner, even though it is used in conjunction with a detailed description of certain specific embodiments of the technology. Certain terms may even be emphasized below; however, any terminology intended to be interpreted in any restricted manner will be specifically defined as such in this Detailed Description section.

The present disclosure relates to quantum devices and methods for making the same. A quantum device comprises a substrate with an insulation surface and at least one quantum component disposed on the insulation surface of the substrate. The at least one quantum component may comprise multiple plateau members and at least one quantum dot. Each plateau member is disposed at an angle against an adjacent plateau member. Each quantum dot is formed within an insulation body and disposed at an included-angle location of two adjacent plateau members of the multiple plateau members. In addition, the at least one quantum component is operable at a temperature above 4 K, including 77 K and even 300 K. To be operable at such a high temperature, each quantum dot may have one or more of the following features: a diameter less than or equal to two times of an exciton Bohr radius of the material of the quantum dot, approximately a spherical shape, single crystallinity, and approximately 100% purity. In one embodiment, each quantum dot comprises semiconductor material, such as germanium. A germanium quantum dot may have a diameter less than approximately 25 nm, including 12 nm, 10 nm, 7 nm, 5 nm, 3 nm, 2 nm, and 1 nm For a quantum device including two or more germanium quantum dots, a distance between two adjacent quantum dots may be less than 20 nm, including 10 nm, 7 nm, 5 nm and 3 nm.

As described above, the properties of a quantum dot may be determined at least by its material, size, shape, strain, purity, crystallinity, and inter-quantum dot spacing (for a quantum component including two or more quantum dots). These properties directly influence the quantum dot electronic structures such as charging energy and energy-level separations. The quantum dot may be made of semiconductor materials, such as Silicon, Germanium, SiGe, GaAs, CdSe, GeSn. The disclosure reveals that a quantum dot whose size is sufficiently small to exhibit a quantum confinement effect may be operable at a high temperature, for example 4 K and above. The Germanium has an exciton Bohr radius at 24.9 nm. Thus, when the diameter of a Germanium quantum dot with approximately spherical shape is less than 24.9 nm, its quantum confinement effect would be observable. The spherical shape of the quantum dot provides isotropic and symmetric feature in connection to quantum confinement effect. When the diameter of the Germanium quantum dot is smaller than 24 nm, such quantum dot may be generated with single crystallinity. Alternatively, through annealing process, the Germanium quantum dot may be converted to single crystallinity. In one embodiment, a quantum dot made of about 100% purity of Germanium with an approximately sphere shape of diameter 12 nm and formed in single crystalline is operable at 77 K and above. The quantum dot is formed within an insulation body, which in one embodiment may be made of silicon dioxide. The insulation body may have an irregular shape with thicker portions and thinner portions.

The at least one quantum component may comprise a first plateau member, a second plateau member, and a first quantum dot. The first plateau member is disposed at an angle against the first plateau member. The first quantum dot is formed within a first insulation body and disposed at an included-angle location of the first plateau member and the second plateau member. Such two plateau members and one quantum dot within an insulation body disposed at an included-angle location of the two plateau members constitute a fundamental structure of various types of quantum components, such as a single electron transistor (SET), a single hole transistor (SHT), a single electron transistor invertor (SETI), a single hole transistor inverter (SHTI), a qubit, and a double qubit. For example, a SET or a SHT may contain two plateau members and one quantum dot. An SETI or SHT may contain three plateau members and two quantum dots. A qubit may contain three plateau members and two quantum dots. A double qubit may contain four plateau members and three quantum dots. In another embodiment, a double qubit may have different configurations, for example containing five plateau members and four quantum dots. These quantum components may be combined by sharing a plateau member. For example, a SET may be combined with a qubit to measure signals of the qubit. This combination may contain four plateau members and three quantum dots because one plateau member is shared by the SET and the qubit.

In addition to plateau members and quantum dots, a quantum component may further comprise control gates, including plunger gates each to control electrostatic potential of a quantum dot and barrier gates each to control the potential of a coupling barrier between two quantum dots. The first category of quantum component types, including SET, SHT, SETI, and SHTI, includes plunger gates only. The second category of quantum component types, including qubit and double qubit, includes both plunger gates and barrier gates. In this disclosure, each plunger gate may be independently addressed to modulate the specific potential of a quantum dot; each barrier gate may be independently addressed to modulate the potential height and coupling strength of a barrier between two quantum dots. Moreover, since these control gates do not overlap with each other, cross-talk effect between these control gates is minimum. For the second category of quantum component types, a barrier is formed between two quantum dots. The barrier height, the barrier width, and the barrier-quantum dot interface may be adjusted, in order to control quantum confinement and the tunability of inter-quantum dot coupling energy (arising from the energy-level splitting of bonding- and anti-bonding states due to electron wave interference). In addition, the crystallinity of the quantum dots and their interfacial properties, as well as the associated coupling barriers strongly relates to the dephasing/decoherence time of the quantum states.

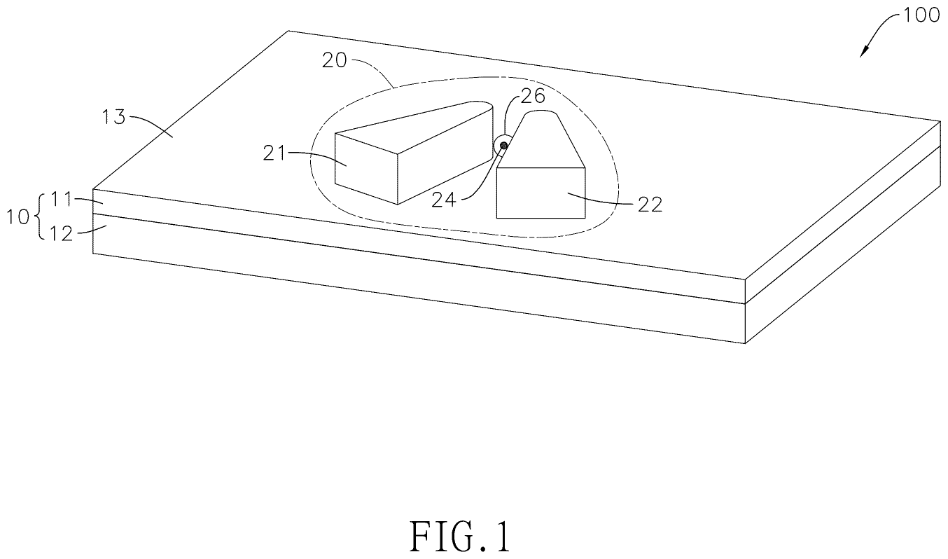

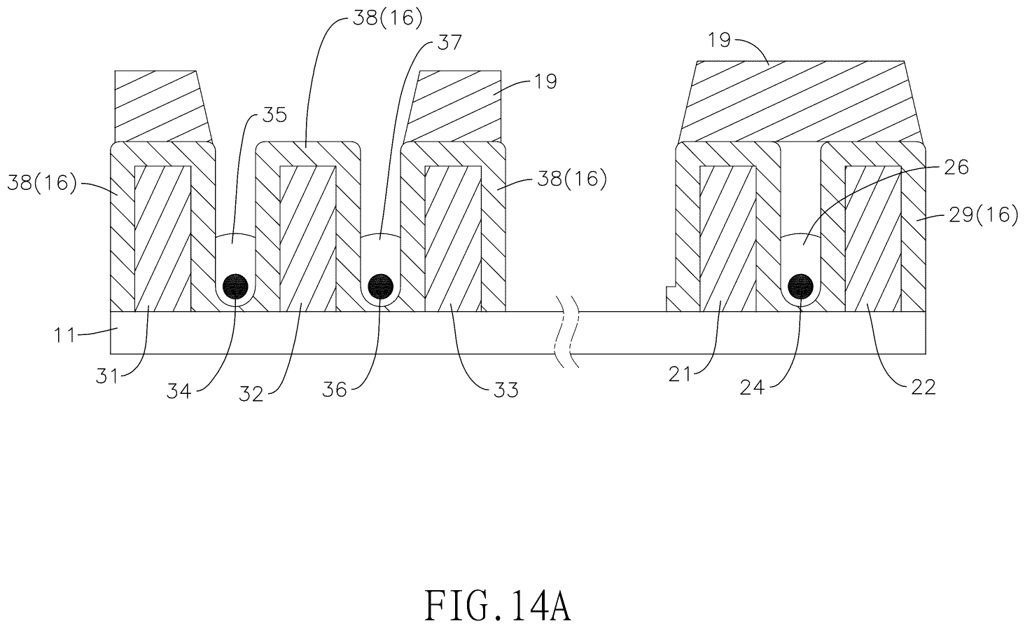

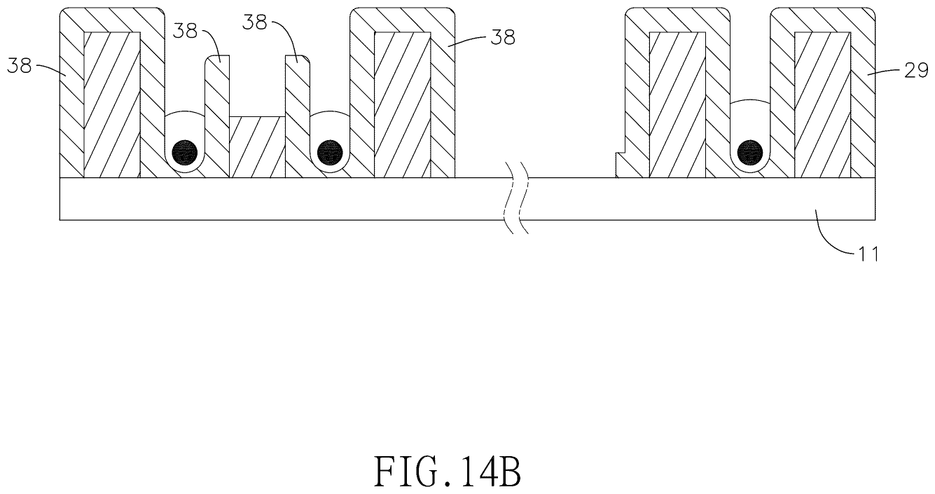

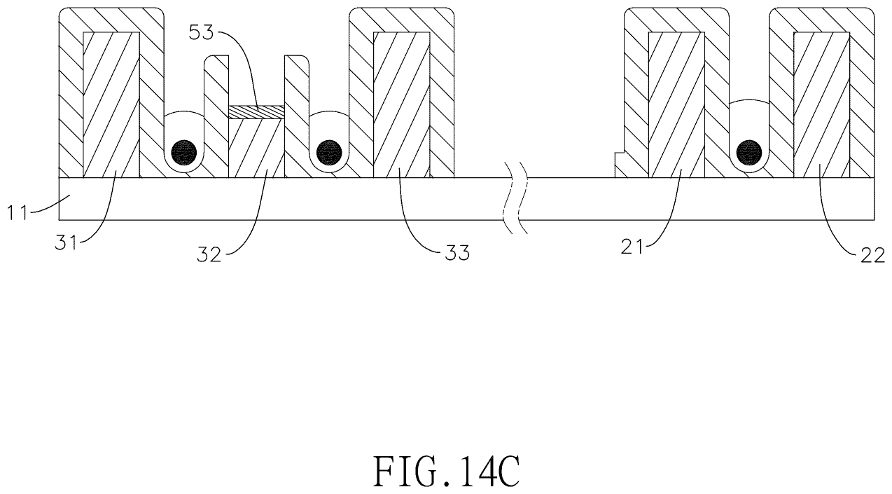

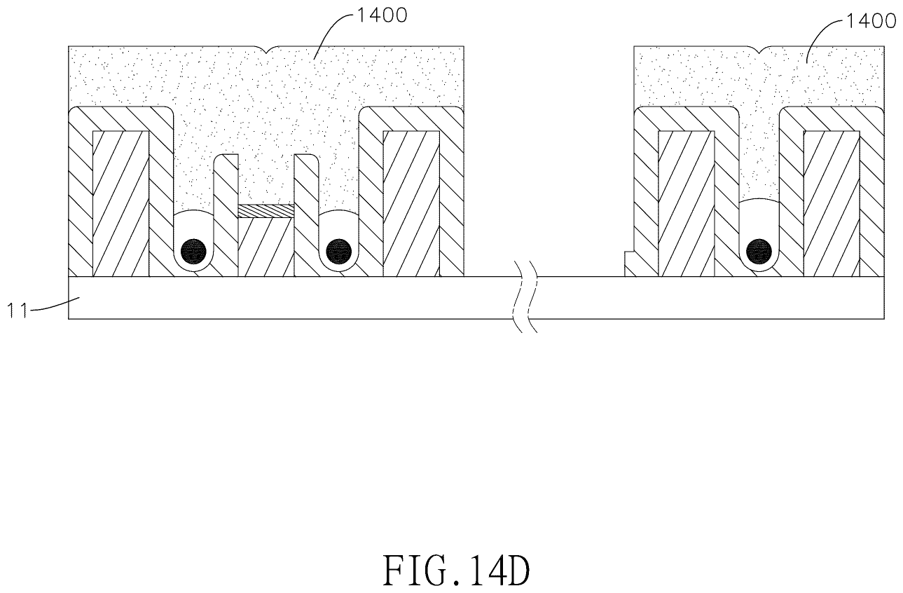

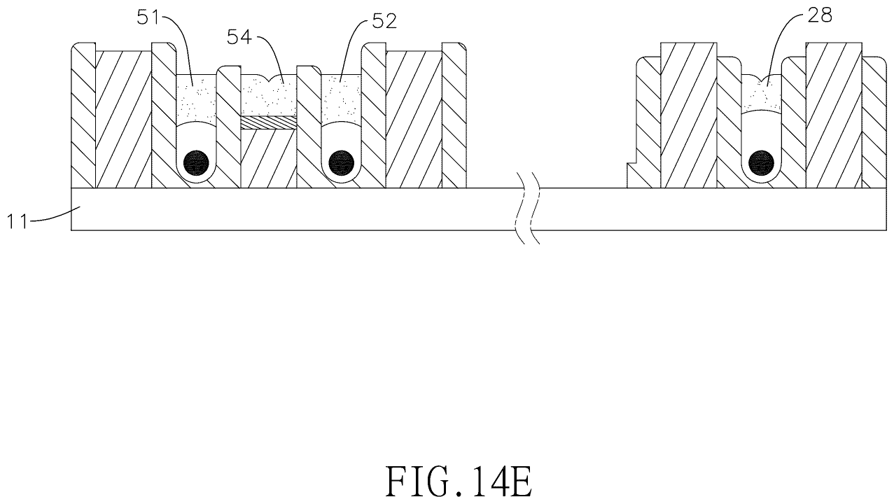

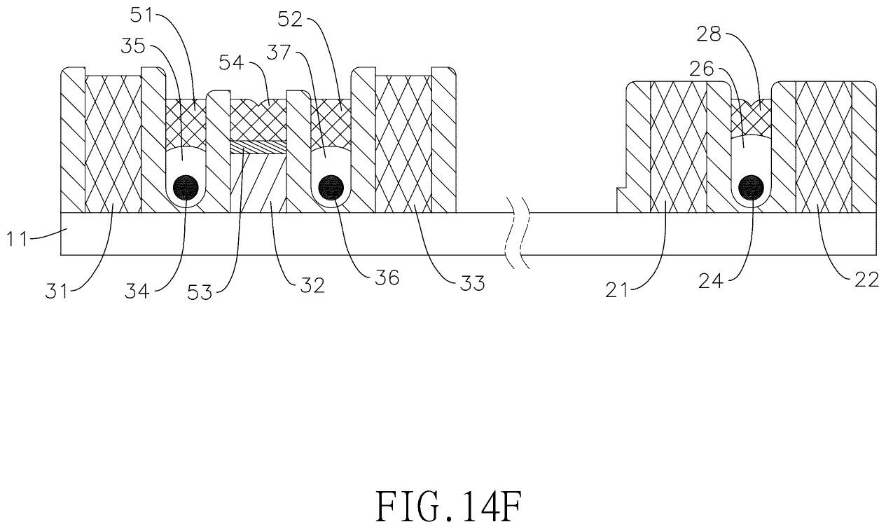

As shown in FIG. 1, a quantum device 100 includes a substrate 10 with an insulation surface 13 and at least one quantum component 20 which is an SET or SHT in this embodiment. The substrate 10 may further include a semiconductor substrate layer 12 and an oxide layer 11. In one embodiment, the substrate 10 includes a silicon substrate layer 12 and a silicon dioxide layer 11. Alternatively, the substrate 10 may be made of silicon carbide or silicon dioxide. The quantum component 20, either an SET or an SHT, includes a first plateau member 21, a second plateau member 22, and a first quantum dot 24 within a first insulation body 26. The second plateau member 22 is separated from the first plateau member 21 and disposed at an angle against the first plateau member 21. The first quantum dot 24 is formed within a first insulation body 26 and disposed at an included-angle location of the first plateau member 21 and the second plateau member 22. Again, in one embodiment, the first quantum dot 24 is with approximately spherical shape to provide isotropic and symmetric feature in connection to quantum confinement effect. The first quantum dot 24 may be made of Germanium. Although the first insulation body 26 may have an irregular shape with thicker portions and thinner portions as shown in FIG. 14A, it is illustrated as a spherical shell covering the first quantum dot 24 in other drawings of this application. The thinner portion of the first insulation body 26 may be made of silicon dioxide with a thickness of about 1-2 nm. The same may apply to other insulation bodies in this application.

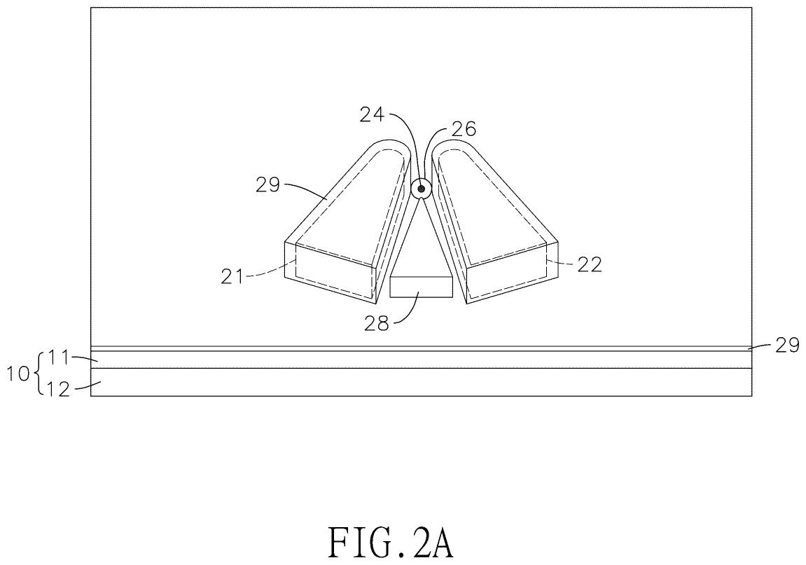

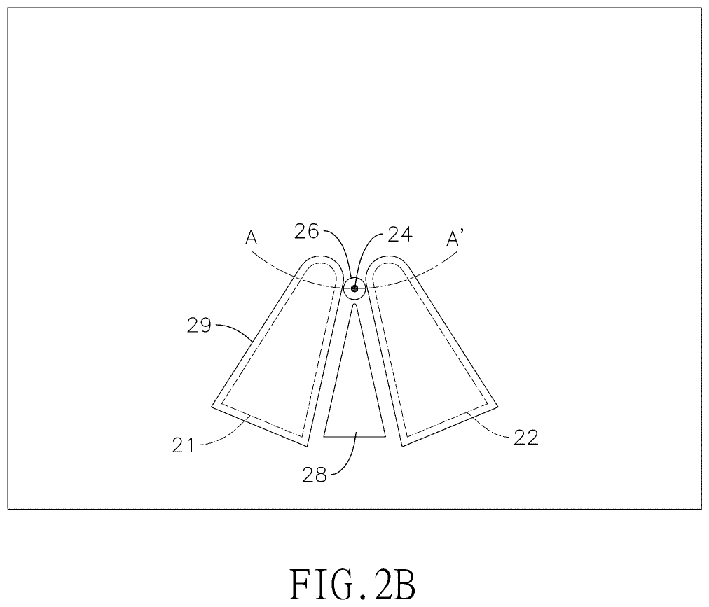

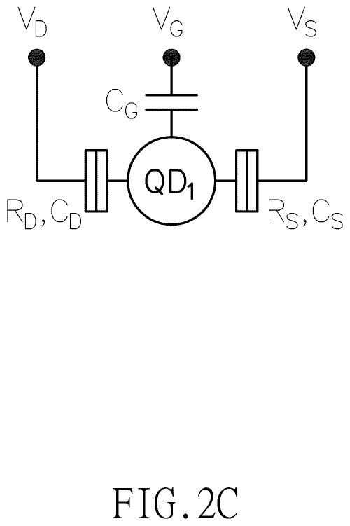

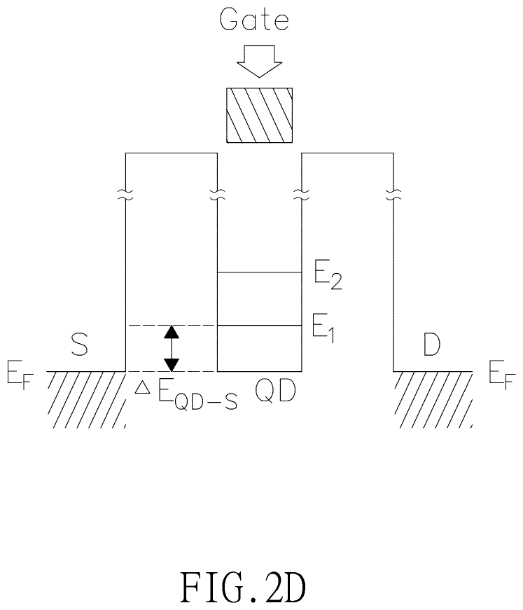

As shown in FIGS. 2A and 2B, the SET or SHT 20 further includes a first plunger gate 28 disposed, in a self-aligned process, adjacent to the first quantum dot 24 to control its electrostatic potential. Before the first plunger gate 28 is formed, a first insulating layer 29 is formed on the first plateau member 21, the second plateau member 22 and the substrate 10. As a result, the first plunger gate 28 is electrically insulated from the first plateau member 21 and the second plateau member 22. In one embodiment, the first insulation layer 29 is made of Si₃N₄. The first plateau member 21 and the second plateau member 22 are conductive and function as reservoirs (respectively a source and a drain) for the SET or the SHT. In one embodiment, for the SET, the first plateau member 21 and the second plateau member 22 are made of heavily-doped N⁺-type semiconductor, such as Arsenic-doped silicon or polysilicon; for the SHT, the first plateau member 21 and the second plateau member 22 are made of heavily-doped P⁺-type semiconductor, such as Boron-doped silicon or polysilicon.

As shown in FIGS. 2B and 2C, the first plateau member 21, for example heavily doped Si (Arsenic-doped or Boron-doped) or polysilicon, when functioned as a drain, is provided with a drain voltage V_{D}. The first insulating layer 29, for example Si₃N₄, and the first insulation body 26 surrounding the first quantum dot 24, for example a SiO₂ shell surrounding a Ge quantum dot, both between the first plateau member 21 and the first quantum dot 24, collectively provide a tunneling capacitor C_{D} and a tunneling resistance R_{D} for the drain. Likewise, the second plateau member 22, for example heavily doped Si (Arsenic-doped or Boron-doped) or polysilicon, when functioned as a source, is provided with a source voltage V_{S}. The first insulating layer 29, for example Si₃N₄, and the first insulation body 26 surrounding the first quantum dot 24, for example a SiO₂ shell surrounding a Ge quantum dot, both between the second plateau member 22 and the first quantum dot 24, collectively provide a tunneling capacitor C_{S} and a tunneling resistance R_{S} for the source. The first plunger gate 28 is provided with a gate voltage V_{G} to capacitively modulate the electrostatic potential of the first quantum dot 24. In other words, the first quantum dot potential could be independently adjusted by the first plunger gate 28. The first insulation body 26 surrounding the first quantum dot 24, for example a SiO₂ shell surrounding the Ge quantum dot, provides a capacitance C_{G} for the first plunger gate 28. Each of the source (the second plateau member 22), the drain (the first plateau member 21), and the first plunger gate 28 may be independently addressed and provided with different voltages.

The basic operation of an SET 20 relies on single charge tunneling from the source into the first quantum dot 24, passing through discrete, well-separated energy levels of the first quantum dot 24, and then tunneling to the drain. As a result, based on the Pauli Exclusion and Coulomb Blockade effects, the SET 20 exhibits highly nonlinear I-V characteristics of Coulomb oscillations and Coulomb staircases. The first plunger gate 28 is placed in proximity to the first quantum dot 28 in order to modulate energy levels of the first quantum dot 24. When the size of the first quantum dot 24 is much smaller than its exciton Bohr radius, for example about 24.9 nm for Ge, the electronic structure of the first quantum dot 24 would possesses discrete, well-separated energy levels instead of continuous energy bands as a result of Quantum Confinement Effects (QCEs). For simplicity, FIG. 2D, a schematic energy band of an SET, shows two discrete and well-separated energy levels, E1 (the ground state) and E2 (the first excited state). Also, continuous density of states below the Fermi-level is almost fully occupied by electron.

Based on the Pauli exclusion principle, only two electrons (spin up and spin down) are allowed to present within one energy level simultaneously. Meanwhile, electrons residing within the first quantum dot would impose a strong Coulomb repulsion force to repel another electrons to tunnel into the quantum dot. In other words, if there is one electron already present at E1 of the first quantum dot, the second electron needs to overcome a potential energy imposed by the existing electron in the first quantum dot, called charging energy (Uee=U1). Herein, the second sublevel of E1 is treated as an individual energy level of E1+U1. If U1 is larger than the energy level separation between E1 and E2 (E(1,2)=E2−E1), the quasi state of E1+U1 would locate higher than E2, otherwise it would sit between E1 and E2as U1<E(1,2). Consequently, the subsequent electron moving from source to the first quantum dot will pass through either the first excited state (E2) or the charging energy state of the ground state (E1+U1) depending on whichever is lower.

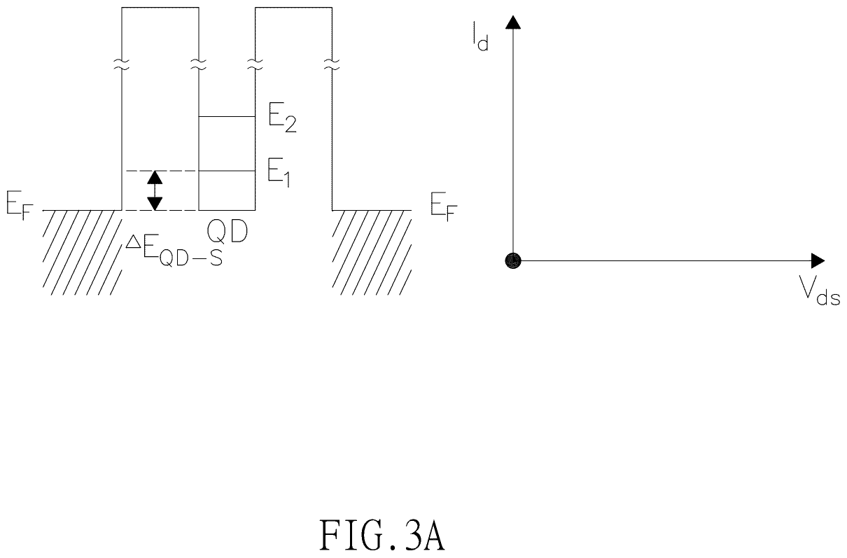

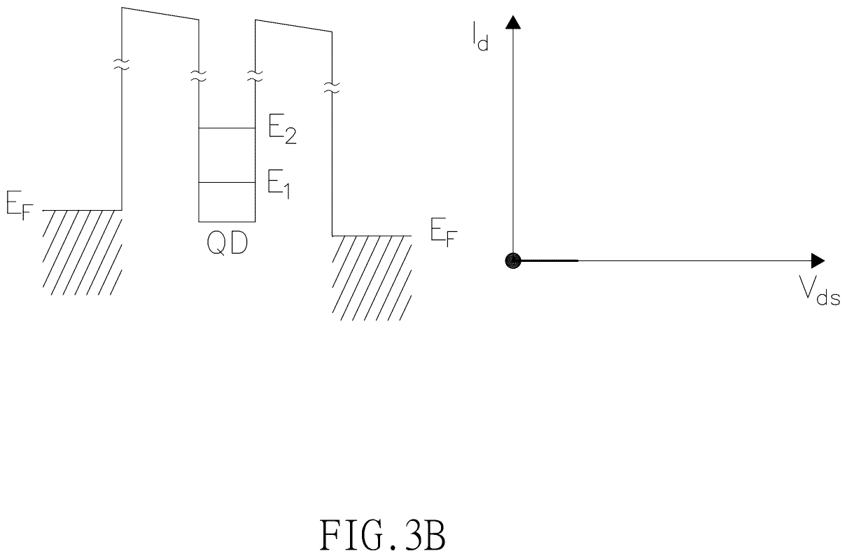

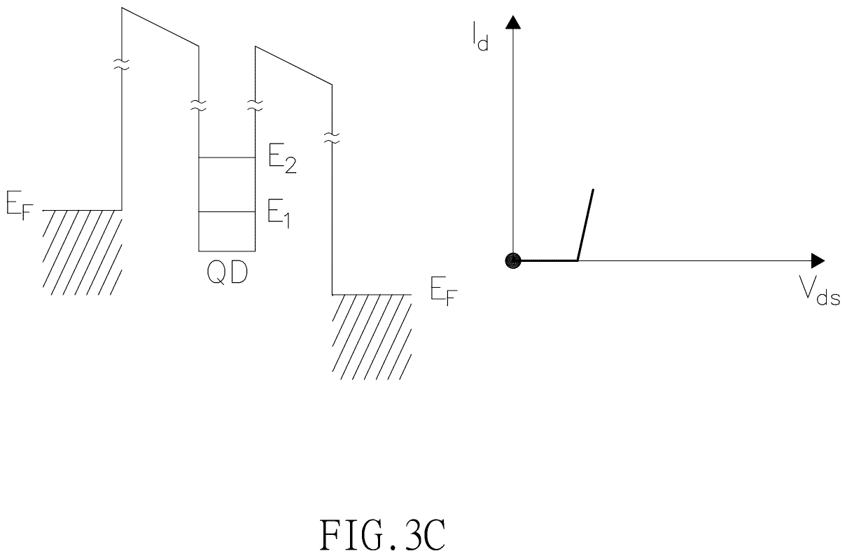

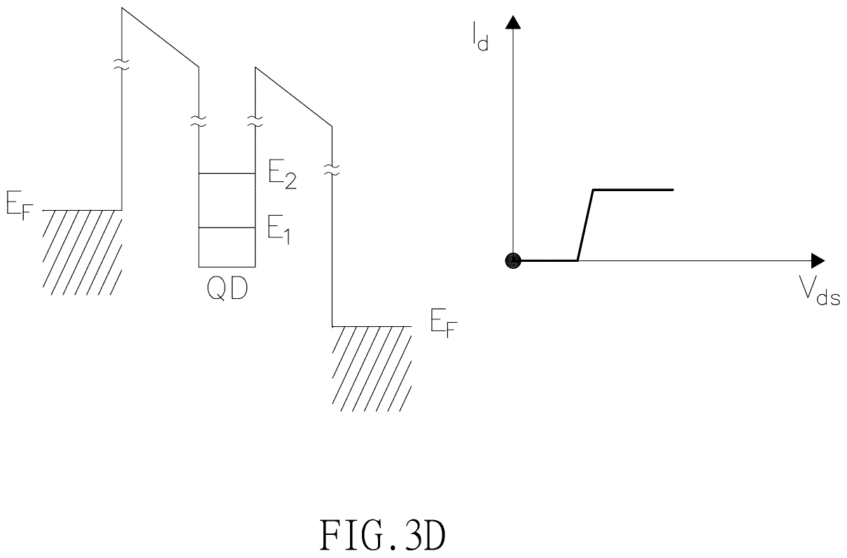

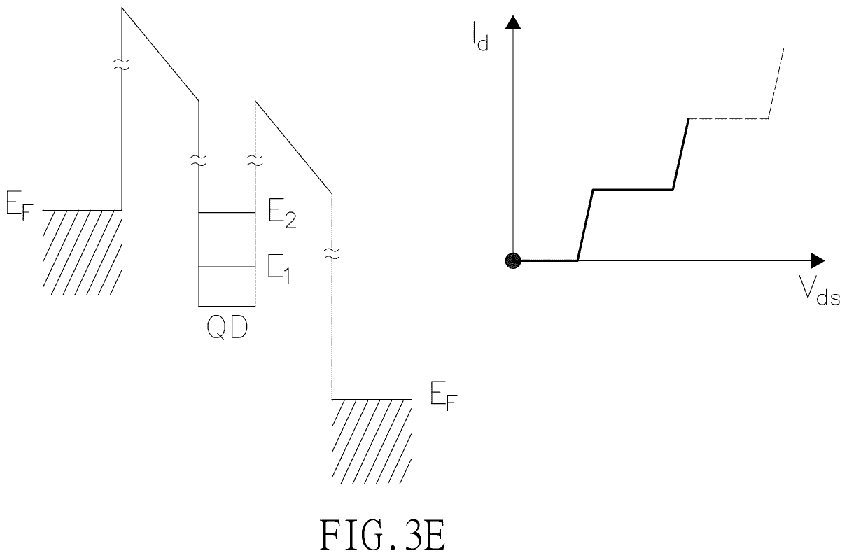

As shown in FIGS. 3A-E, this paragraph describes V_{DS} (voltage difference between V_{D} and V_{S}) manipulation at a given gate voltage V_{G}. A positive V_{DS} (voltage difference between V_{D} and V_{S}) would pull down the Fermi-level of the drain, causing band bending across the tunneling barriers, and then descend the energy levels in the first quantum dot. Initially, as shown in FIG. 3A, the ground state of the first quantum dot is greater than Fermi level of source/drain by EQD-S at an equilibrium state when no bias is applied). A small V_{DS} applied to the drain is insufficient to make the ground state of the first quantum dot lower than the Fermi-level of the source, so that there is no available energy states for electrons injection from the source and thus, no current flow at all, as shown in FIG. 3B. When gradually increasing V_{DS} to a given threshold voltage (V_{DS}⁺) at which the ground state of the first quantum dot gets resonant with the Fermi-level of the source, electrons start to tunnel through the tunneling junction into the ground state of the first quantum dot, as shown in FIG. 3C. A further increment in V_{DS} can retain the ground state of the first quantum dot in resonance with the source but is insufficient to make the first excited state lineup with the Fermi level of the source reservoir, leading to a constant current plateau as shown in FIG. 3D. When source electrons get resonance with the second available energy state of the first quantum dot, either the first excited state (E2) or the quasi level of E1+U1, by applying a greater V_{DS}, both the second available energy state and the ground state are allowed for electrons transport simultaneously, leading to a second current plateau, as shown in FIG. 3E. Consecutive current staircases are as a consequence of a continuous increase in applied V_{DS}, leading to typical nonlinear output characteristics.

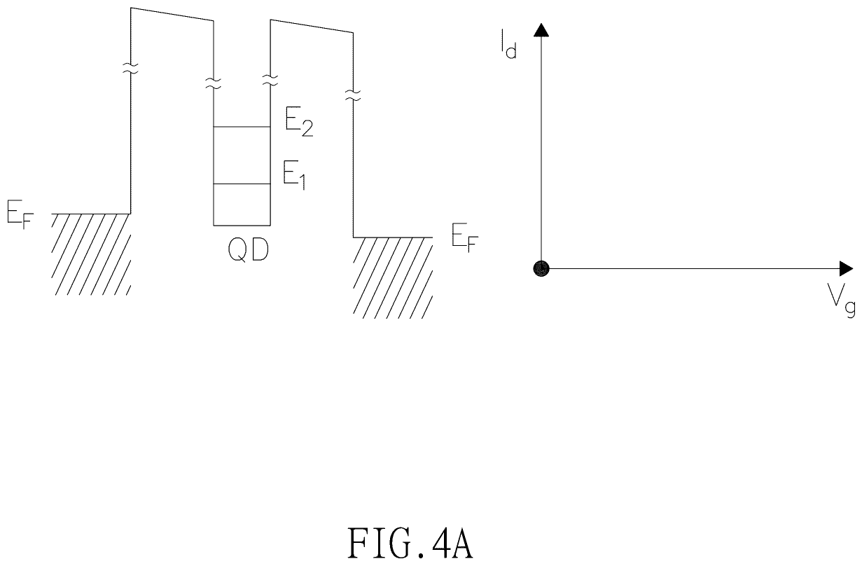

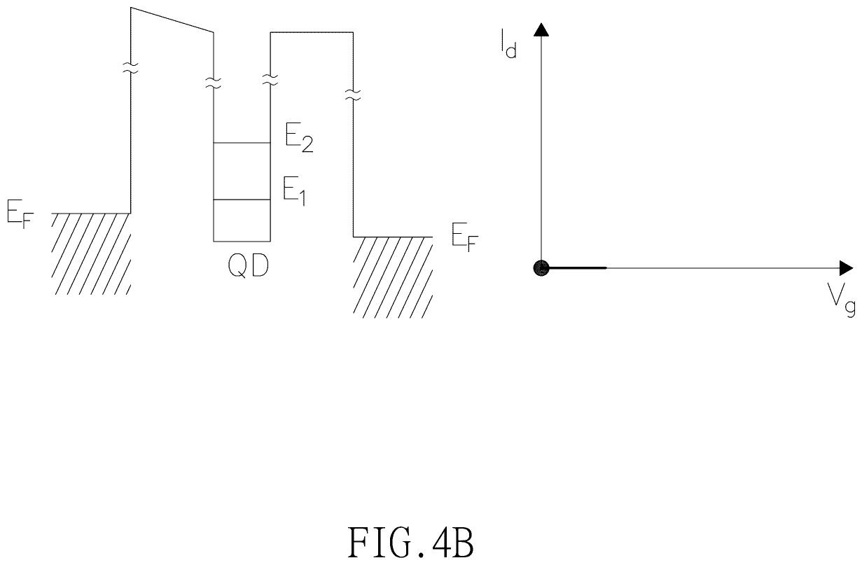

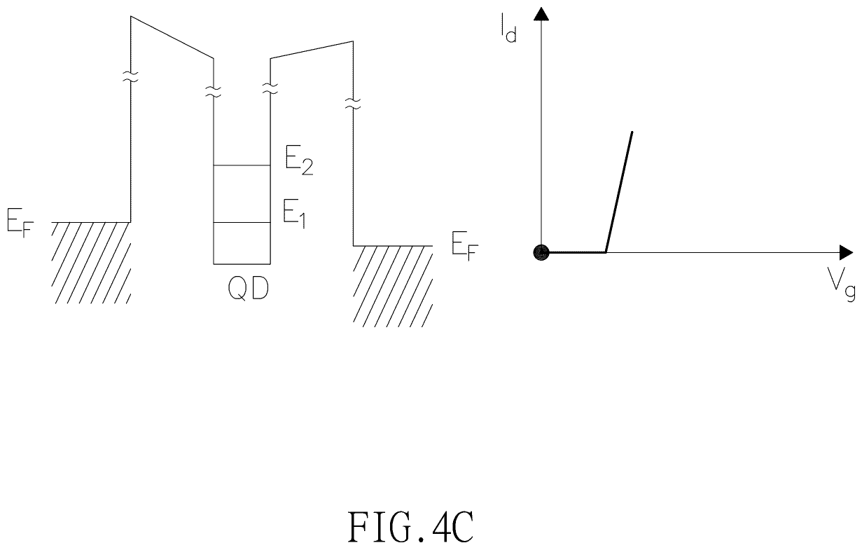

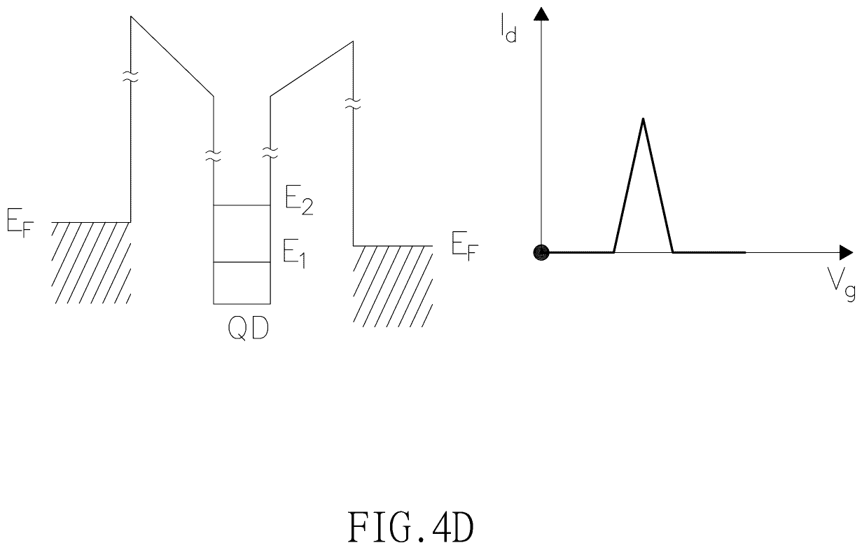

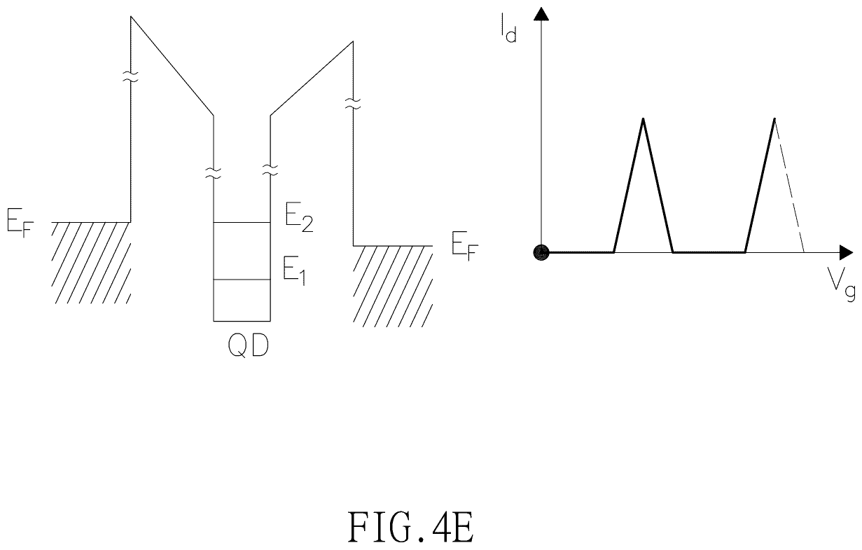

As shown in FIGS. 4A-4E, this paragraph describes gate voltage V_{G} manipulation at a given V_{DS} (voltage difference between V_{D} and V_{S}). The SET 20 has a first plunger gate 28 that is self-aligned with the first quantum dot 24 in order to simply manipulate the electronic structure of the first quantum dot 24 but not influence tunneling barriers significantly. Initially, as shown in FIG. 4A, a small V_{DS} is applied to induce a slight potential difference between the source and the drain but such a drain bias is insufficient to make energy levels of the first quantum dot 24 line up with Fermi level of source reservoir. At the condition of near zero or small V_{G} bias where the ground state of the quantum dot is still higher than the Fermi level of source, electrons are prohibited to travel into the forbidden gap, resulting in no current flow, as shown in FIG. 4B. Increasing V_{G} to line up the ground state of the first quantum dot 24 with the Fermi level of the source, electrons are able to tunnel from the source through the tunneling potential barrier into the first quantum dot 24 and then tunnel to the drain one by one, inducing a significant tunneling current, as shown in FIG. 4C. As further increasing V_{G} to pull down the ground state of the first quantum dot 24 below the Fermi-level of the drain, the electron within the first quantum dot 24 would be trapped wherein rather than go out to the drain since there is no available state below the Fermi level of the drain, leading to a sudden current drop, as shown FIG. 4D. Such a current increment and then current drop form the first oscillatory current peak. No current flow is allowed with an increase in V_{G} until the second available state in the first quantum dot, either the first excited state (E2) or the quasi level of E1+U1, becomes line-up with the Fermi-level of the source. Afterwards the tunneling current would jump up and then decline again once the second available state in the first quantum dot 24 gets resonant with the source and then moves below the Fermi level of the drain, forming the second current peak, as shown in FIG. 4E. This is the most representative, gate-induced nonlinear current behaviors for an SET-Coulomb oscillations.

Thus, the SET or SHT 20, comprising a first quantum dot 24 capacitively coupled to the source/drain reservoirs (the first plateau member 21 and the second plateau member 22) and the first plunger gate 28 through confinement barriers, may function as a high-precision charge and differential current/voltage sensing device to measure itinerant current with single charge precision based on Coulomb blockade effects. Thus, the SET or SHT 20 may be arranged in close proximity to a qubit quantum component to sense minute variations of local potentials induced by charge movement between two quantum dots of the qubit.

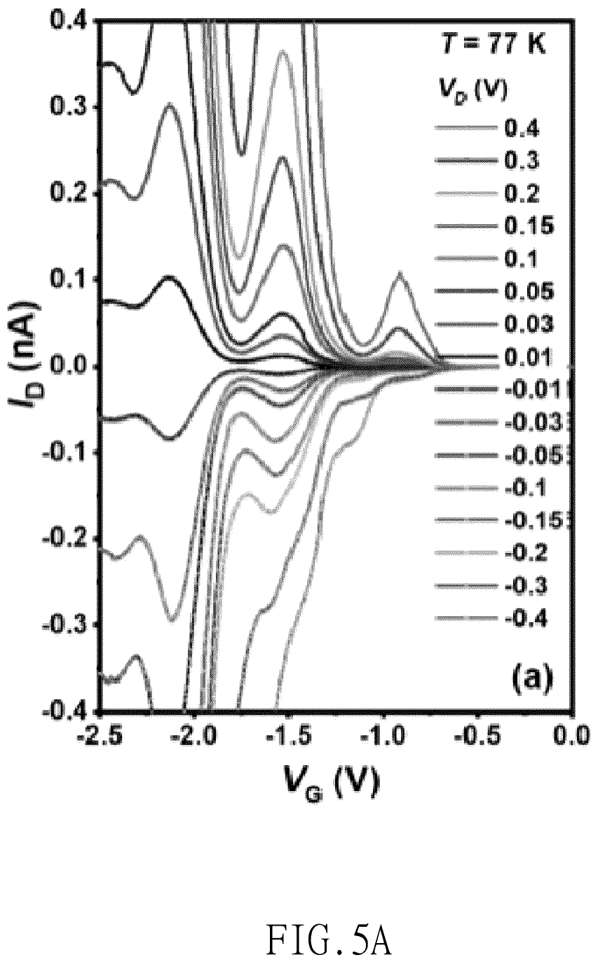

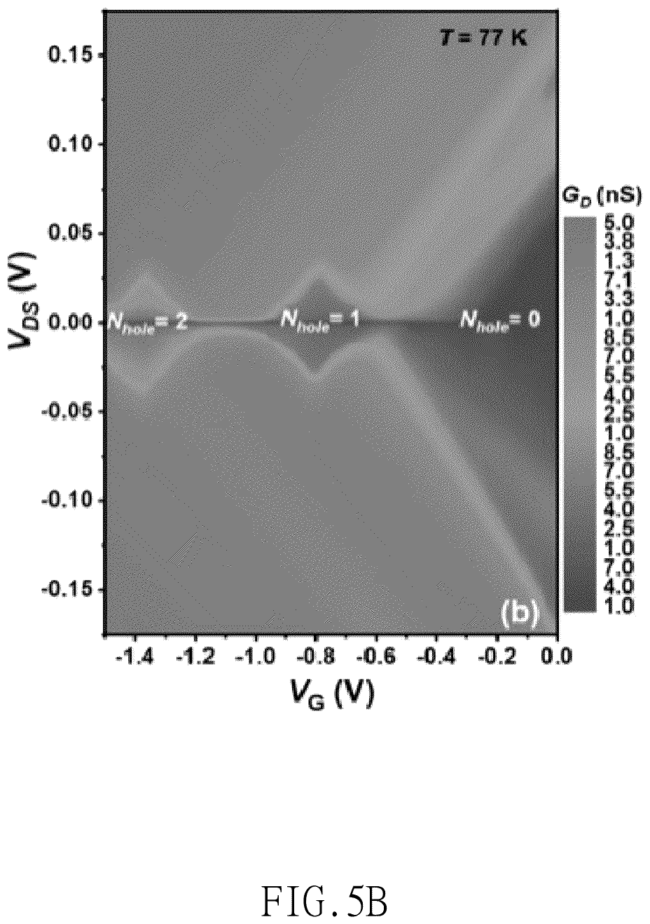

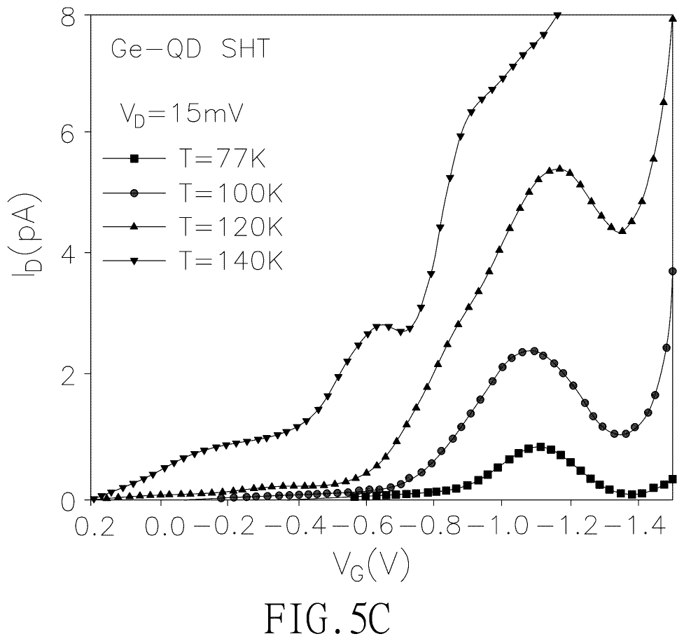

In one embodiment, the above described SHT 20, comprising a spherical-shaped Ge quantum dot 24 with a diameter of about 11 nm, is operable at 77 K. FIGS. 5A and 5B respectively show experimental characteristics of I_{D}-V_{D}-V_{G} curves (FIG. 5A) and Coulomb stability diagram (FIG. 5B) of Ge quantum dot SHT contour plot measured at temperature of 77 K. Clear oscillatory current behaviors and well-sealed Coulomb diamonds are testament to the proof-of-principle Ge quantum dot electronic devices operation. Each oscillatory current peak corresponds to a change of one additional hole within the Ge quantum dot as a result of strong Coulomb blockade effect. Each node between Coulomb diamonds represents one additional hole tunneling through one-particle energy levels or overcoming particle Coulomb interactions. Estimated single addition energy for holes through the Ge quantum dot is larger than 25 meV from the slopes and voltage periodicity of the corresponding diamonds in FIG. 5B. When the spherical-shaped Ge quantum dot with a diameter at about 7 nm, such SHT quantum component 20 is operable at 300 K. In a similar embodiment, as shown in FIG. 5C, the SHT 20, including a spherical-shaped Ge quantum dot 24 with a diameter of about 10 nm, is operable from 77 K to at least 140 K. FIG. 5C compares I_{D}-V_{G} curves of Ge quantum dot SHTs measured at 77-140 K. SHTs exhibit well controlled tunneling peaks due to the single valley and isotropic mₕ* for hole. Estimated charging energy for holes through energy levels of such a 10 nm Ge quantum dot is in the range of 47-78 meV.

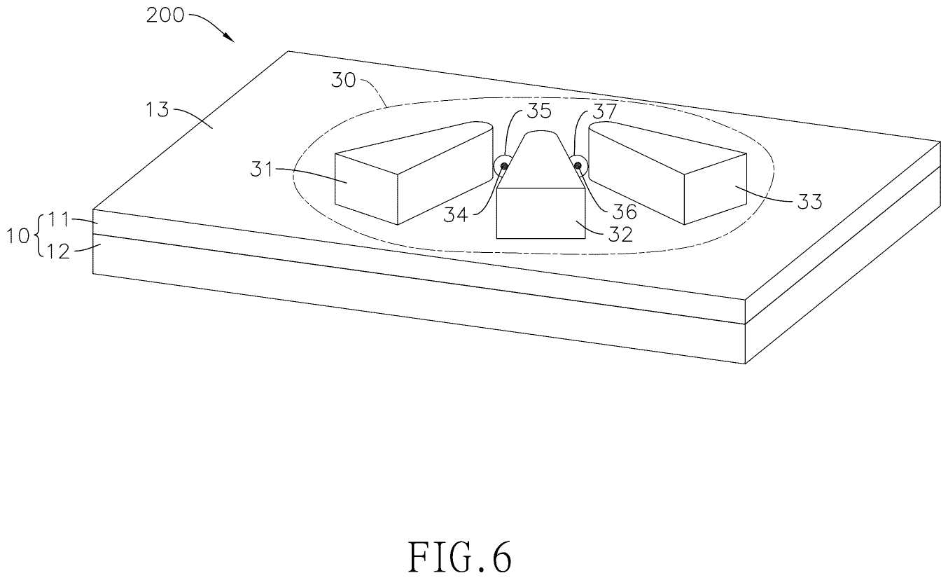

As shown in FIG. 6, a quantum device 200 includes a substrate 10 with an insulation surface 13 and at least one quantum component 30 which may serve as a single electron transistor invertor (SETI) or a single hole transistor inverter (SHTI) or a qubit in this embodiment. An SETI has two SETs connected in series. An SHTI has two SHTs connected in series. A qubit, here containing two quantum dots, is a quantum bit, the counterpart in quantum computing to the binary digit or bit of classical computing. Just as a bit is the basic unit of information in a classical computer, a qubit is the basic unit of information in a quantum computer.

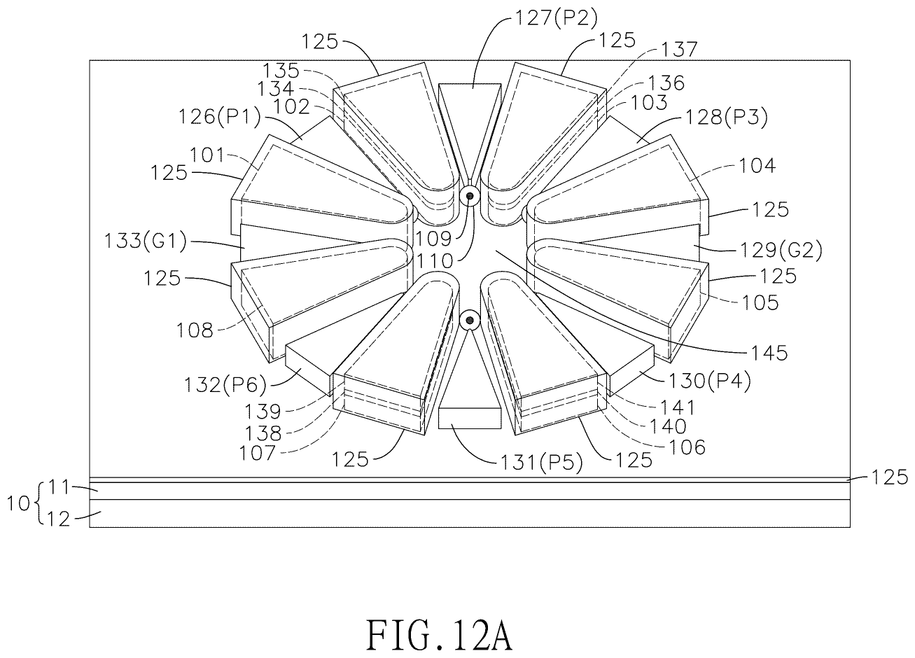

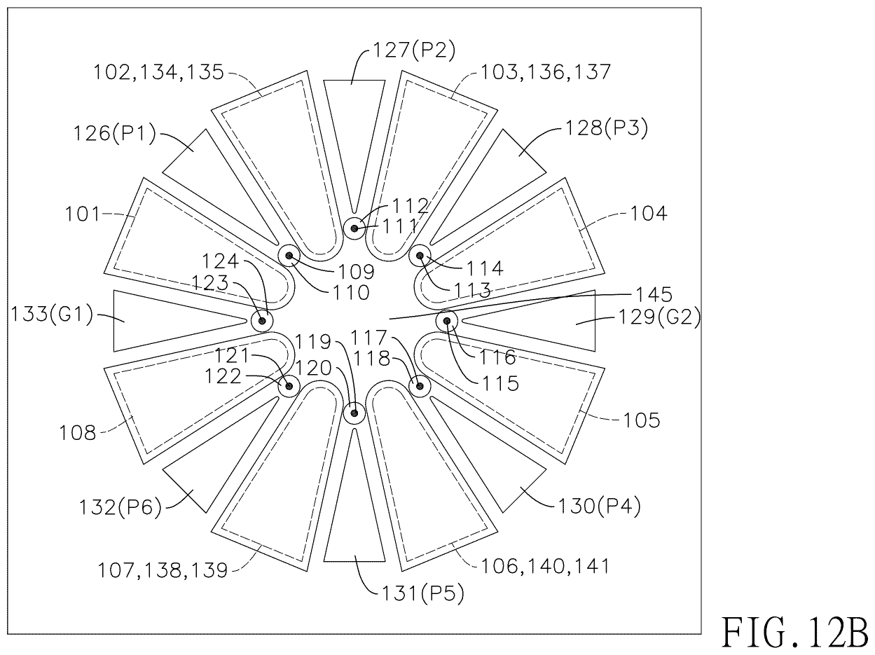

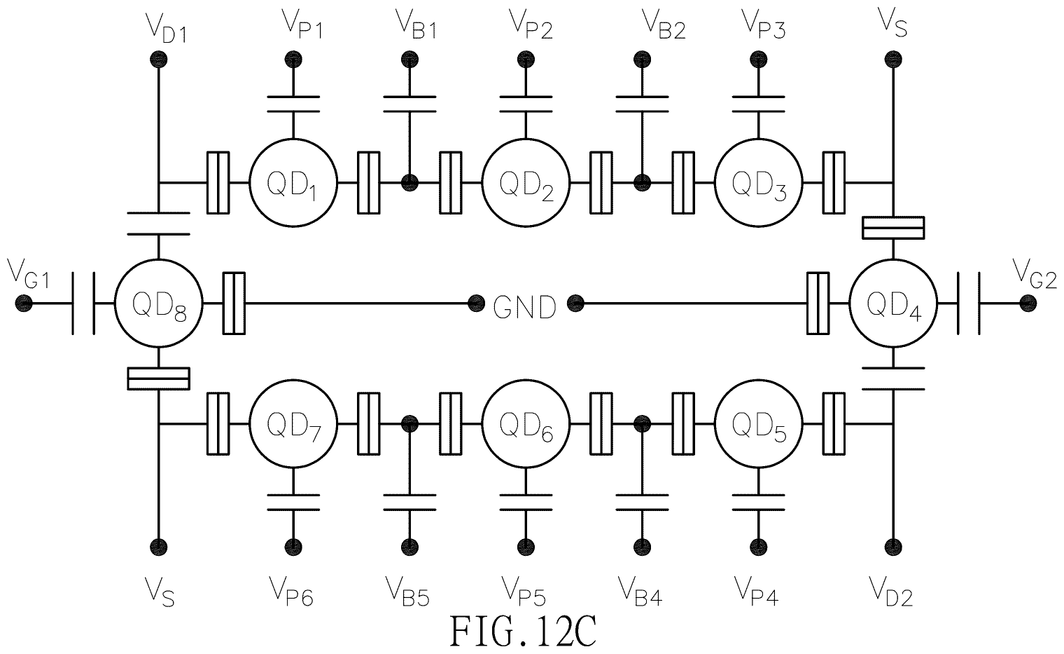

The substrate 10 may further include a semiconductor substrate layer 12 and an oxide layer 11. In one embodiment, the substrate 10 includes a silicon substrate layer 12 and a silicon dioxide layer 11. Alternatively, the substrate 10 may be made of silicon carbide or silicon dioxide. The quantum component 30 includes a first plateau member 31, a second plateau member 32, a third plateau member 33, a first quantum dot 34 within a first insulation body 35, and a second quantum dot 36 (not shown) within a second insulation body 37 (not shown). The second plateau member 32 is separated from the first plateau member 31 and disposed at an angle against the first plateau member 31. Likewise, the third plateau member 33 is separated from the second plateau member 32 and disposed at an angle against the second plateau member 32. The first quantum dot 34 is disposed at an included-angle location of the first plateau member 31 and the second plateau member 32. Likewise, the second quantum dot 36 is disposed at an included-angle location of the second plateau member 32 and the third plateau member 33. Again, in one embodiment, the first quantum dot 34 and the second quantum dot 36 are of approximately spherical shape to provide isotropic and symmetric feature in connection to quantum confinement effect. The first quantum dot 34 and the second quantum dot 36 may be made of Germanium. Each of the first insulation body 35 and the second insulation body 37 may have an irregular shape with thicker portions and thinner portions as shown in FIG. 12A but is illustrated as a spherical shell in other drawings. In one embodiment, each insulation body may be made of silicon dioxide with a thickness about 1-2 nm at the thinner portion contacting Si₃N₄, respectively surrounding the first quantum dot 34 and the second quantum dot 36.

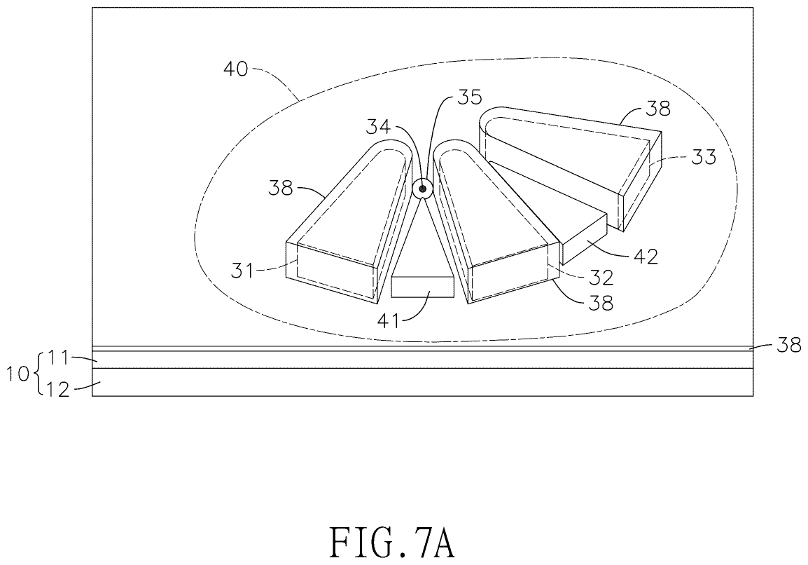

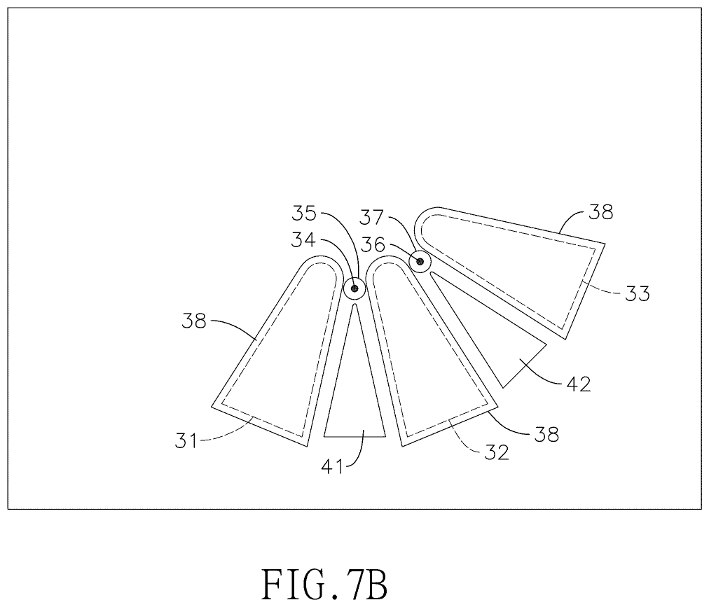

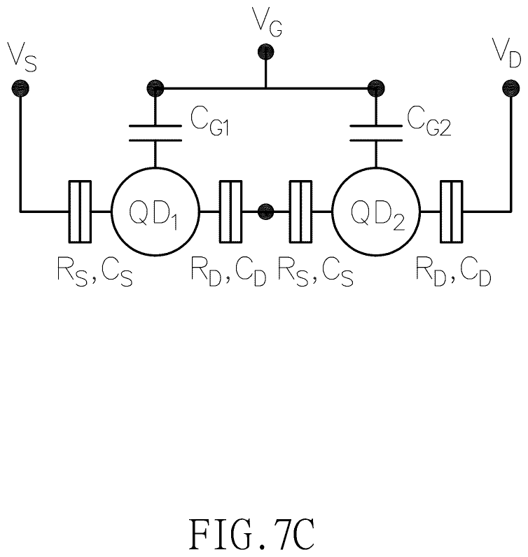

As shown in FIGS. 7A-7C, the quantum component 30 is an SETI (two SETs connected in series) or SHTI (two SHTs connected in series) 40. For example, the first plateau member 31, the second plateau member 32, and the first quantum dot 34 within the first insulation body 35 constitute a first SET. The second plateau member 32, the third plateau member 33, and the second quantum dot 36 (not shown) within the second insulation body 37 (not show) constitute a second SET. The SETI or SHTI quantum component 40 further includes a first plunger gate 41 disposed, in a self-aligned process, adjacent to the first quantum dot 34 and between the first plateau member 31 and the second plateau member 32. The second plunger gate 42 disposed, in a self-aligned process, adjacent to the second quantum dot 36 and between the second plateau member 32 and the third plateau member 33.

A first insulating layer 38 is formed on the first plateau member 31, the second plateau member 32, the third plateau member 33 and the substrate 10. Then, the first plunger gate 41 is disposed, in a self-aligned process, adjacent to the first quantum dot 34, to capacitively modulate the electrostatic potential of the first quantum dot 34. Likewise, the second plunger gate 42 is disposed, in a self-aligned process, adjacent to the second quantum dot 36, to capacitively modulate the electrostatic potential of the second quantum dot 36. As a result, the first plunger gate 41 and the second plunger gate 42 are electrically insulated from the first plateau member 31, the second plateau member 32, and the third plateau member 33. In one embodiment, the first insulation layer 38 is made of Si₃N₄. The first plateau member 31, the second plateau member 32, and the third plateau member 33 are conductive. The first plateau member 31 functions as a source of the first SET; the second plateau member 32 functions as a drain of the first SET and also a source of the second SET; the third plateau member 33 functions as a drain of the second SET. For an SETI, the first plateau member 31, the second plateau member, and the third plateau member 33 are made of N+ type semiconductor, such as Boron-doped silicon or polysilicon. For an SHTI, the first plateau member 31, the second plateau member 32, and the third plateau member 33 are made of P+ type semiconductor, such as Arsenic-doped silicon or polysilicon.

As shown in FIG. 7C, the first plateau member 31, for example heavily doped Si or polysilicon, when functioned as a source of the first SET or SHT, is provided with a source voltage V_{S}. The first insulating layer 38, for example Si₃N₄, and the first insulation body 35 surrounding the first quantum dot 34, for example SiO₂, both between the first quantum dot 34 (QD1) and the first plateau member 31, collectively provide a tunneling capacitor C_{S} and a tunneling resistance R_{S} for the source of the first SET or SHT. Likewise, The first insulating layer 38, for example Si₃N₄, and the first insulation body 35 surrounding the first quantum dot 34, for example SiO₂, both between the first quantum dot 34 and the second plateau member 32, collectively provide a tunneling capacitor C_{D} and a tunneling resistance R_{D} for the drain of the first SET or SHT. The third plateau member 33, for example heavily doped Si or polysilicon, when functioned as a drain of the second SET or SHT, is provided with a drain voltage V_{D}. The first insulating layer 38, for example Si₃N₄, and the second insulation body 37 surrounding the second quantum dot 36, for example SiO₂, both between the second quantum dot 36 and the second plateau member 32, collectively provide a tunneling capacitor C_{S} and a tunneling resistance R_{S} for the source of the second SET or SHT. Likewise, the first insulating layer 38, for example Si₃N₄, and the second insulation body 37 surrounding the second quantum dot 36, for example SiO₂, both between the second quantum dot 36 and the third plateau member 33, collectively provide a tunneling capacitor C_{D} and a tunneling resistance R_{D} for the drain of the second SET or SHT. Both the first plunger gate 41 and the second plunger gate 42 are provided with a gate voltage V_{G} to capacitively modulate the electrostatic potential of the first quantum dot 34 and the second quantum dot 36. The first insulation body 35 surrounding the first quantum dot 34, for example SiO₂, provides a capacitance C_{G1} for the first plunger gate 41. Likewise, the second insulation body 37 surrounding the second quantum dot 36, for example SiO₂, provides a capacitance C_{G2} for the second plunger gate 42. Each of the source, drain, and both the plunger gates may be independently addressed and provided with different voltages.

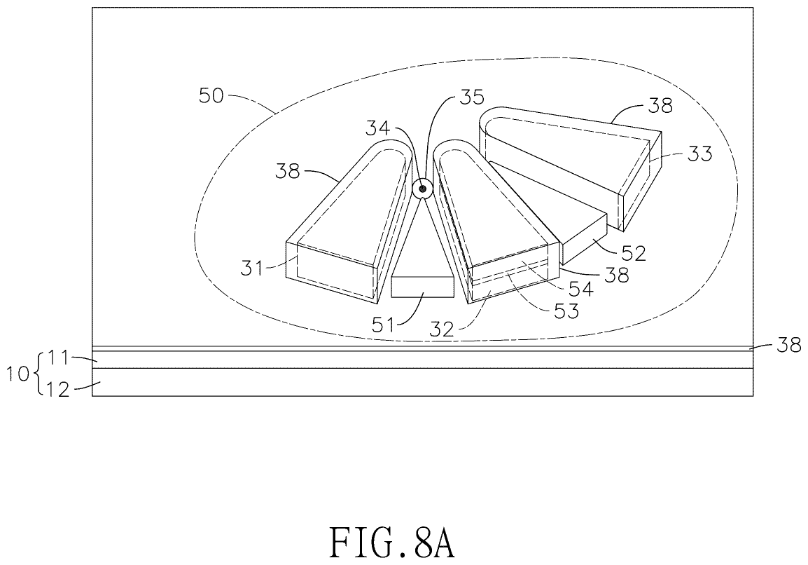

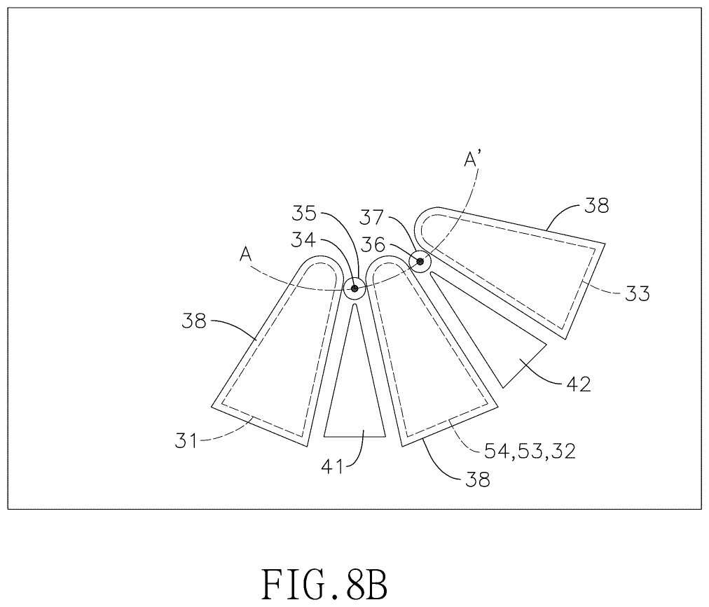

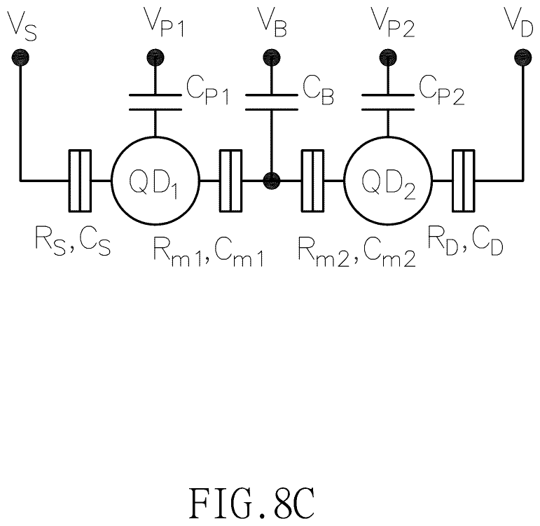

As shown in FIGS. 8A-8B, the quantum component 30 is a qubit 50 in this embodiment, which further includes a first plunger gate 51 disposed, in a self-aligned process, adjacent to the first quantum dot 34 and between the first plateau member 31 and the second plateau member 32. The second plunger gate 52 disposed, in a self-aligned process, adjacent to the second quantum dot 36 and between the second plateau member 32 and the third plateau member 33. A first barrier gate 54 disposed adjacent to the second plateau member 32 and between the first plunger gate 51 and the second plunger gate 52.

A first insulating layer 38 is formed on the first plateau member 31, the second plateau member 32 and the third plateau member 33. Then, the first plunger gate 51 is disposed, in a self-aligned process, adjacent to the first quantum dot 34 to control its quantum confinement effect. Likewise, the second plunger gate 52 is disposed, in a self-aligned process, adjacent to the second quantum dot 36 to control its quantum confinement effect. As a result, the first plunger gate 51 and the second plunger gate 52 are electrically insulated from the first plateau member 31, the second plateau member 32, and the third plateau member 33. In one embodiment, the first insulation layer 38 is made of Si₃N₄. The first plateau member 31 and the third plateau member 33 are conductive and function as reservoirs (respectively a source and a drain) for the qubit quantum component. In one embodiment, the first plateau member 31 and the third plateau member 33 are made of P type or N type semiconductor, such as Arsenic-doped or Boron-doped silicon or polysilicon. The second plateau member 32 is non-conductive and function as coupling barrier (CB) between the first quantum dot 34 and the second quantum dot 36. The first barrier gate 54 is disposed, in a self-aligned process, on a second insulating layer 53 on top of the second plateau member 32, and between the first plunger gate 51 and the second plunger gate 52. In one embodiment, the second plateau member 32 in the qubit 50 here has only about half of the thickness of the first and third plateau members 31, 33. The first barrier gate 54 is insulated from the second plateau member 32 (functioning as CB) by a second insulating layer 53. In one embodiment, the second plateau member 32 is made of single crystalline silicon; the first barrier gate 54 is made of polysilicon; and the second insulating layer 53 is made of silicon dioxide.

As shown in FIG. 8C, the first plateau member 31, for example doped Si or Poly, when functioned as a source, is provided with a source voltage V_{S}. The first insulating layer 38, for example Si₃N₄, and the first insulation body 35 surrounding the first quantum dot 34, for example SiO₂, both between the first quantum dot 34 and the first plateau member 31, collectively provide a tunneling capacitor C_{S} and a tunneling resistance R_{S} for the source. Likewise, the third plateau member 33, for example doped Si or Poly, when functioned as a drain, is provided with a drain voltage V_{D}. The source voltage V_{S} and the drain voltage V_{D} are used for injecting and collecting charges. The first insulating layer 38, for example Si₃N₄, and the second insulation body 37 surrounding the second quantum dot 36, for example SiO₂, both between the second quantum dot 36 and the third plateau member 33, collectively provide a tunneling capacitor C_{D} and a tunneling resistance R_{D} for the drain. The first plunger gate 51 is provided with a voltage V_{P1} to capacitively modulate the electrostatic potential of the first quantum dot 34. In other words, the first quantum dot potential could be independently adjusted by the first plunger gate 51. The first insulation body 35 surrounding the first quantum dot 34, for example SiO₂, provides a capacitance C_{P1} for the first plunger gate 51. Likewise, the second plunger gate 52 is provided with a voltage V_{P2} to capacitively modulate the electrostatic potential of the second quantum dot 36. In other words, the second quantum dot potential could be independently adjusted by the second plunger gate 52. The second insulation body 37 surrounding the second quantum dot 36, for example SiO₂, provides a capacitance C_{P2} for the second plunger gate 52. The first barrier gate 54 is provided with a voltage V_{B} to tune the potential of the coupling barrier between the first quantum dot and the second quantum dot. The second insulating layer 53 provides a barrier capacitance C_{B} for the first barrier gate 54. The first insulating layer 38, for example Si₃N₄, and the first insulation body 35 surrounding the first quantum dot 34, for example SiO₂, both between the first quantum dot 34 and the second plateau member 32, collectively provide a coupling capacitor C_{M1} and a coupling resistance R_{M1}. The first insulating layer 38, for example Si₃N₄, and the second insulation body 37 surrounding the second quantum dot 36, for example SiO₂, both between the second quantum dot 36 and the second plateau member 32, collectively provide a coupling capacitor C_{M2} and a coupling resistance R_{M2}. Each of the source, the drain, the first plunger gate, the second plunger gate, and the first barrier gate may be independently addressed and provided with different voltages.

For a double-quantum-dots (DQD) charge qubit described above, three types of operations, Larmor oscillations, Rabi oscillations and Ramsey fringes, may be used by conducting initialization, manipulation, and measurement of quantum states of such a DQD charge qubit to gain an insight of inter-quantum dot coupling energy and charge decoherence (relaxation time: T1 and dephasing time: T2*).

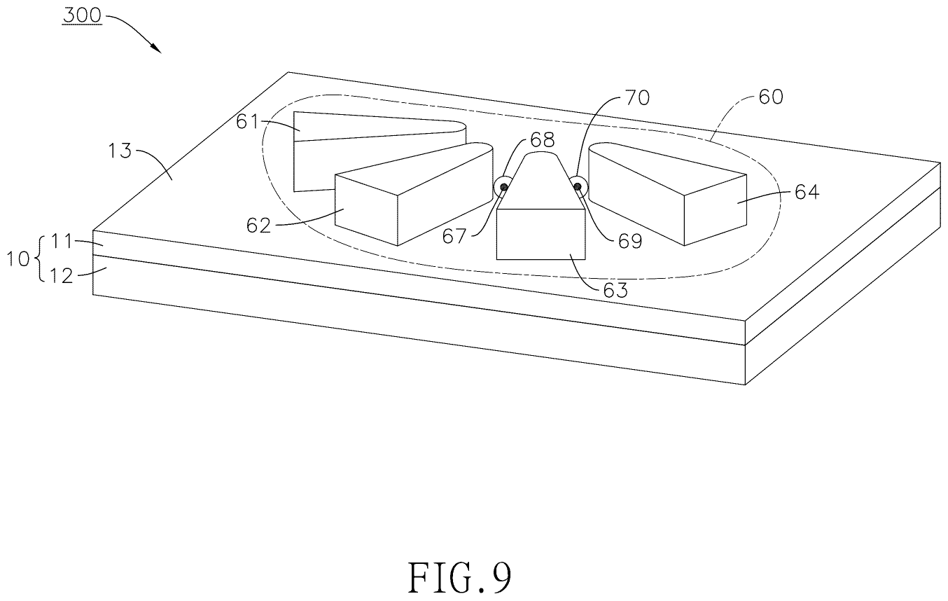

As shown in FIG. 9, a quantum device 300 includes a substrate 10 with an insulation surface 13 and at least one quantum component 60 which may serve as a double qubit. As described before, the substrate 10 may further include a semiconductor substrate layer 12 and an oxide layer 11. In one embodiment, the substrate 10 includes a silicon substrate layer 12 and a silicon dioxide layer 11. Alternatively, the substrate 10 may be made of silicon carbide or silicon dioxide. The quantum component 60 includes a first plateau member 61, a second plateau member 62, a third plateau member 63, a fourth plateau member 64, a first quantum dot 65 (not shown) within a first insulation body 66 (not shown), a second quantum dot 67 within a second insulation body 68, and a third quantum dot 69 within a third insulation body 70. The second plateau member 62 is separated from the first plateau member 61 and disposed at an angle against the first plateau member 61. The third plateau member 63 is separated from the second plateau member 62 and disposed at an angle against the second plateau member 62. Likewise, the fourth plateau member 64 is separated from the third plateau member 63 and disposed at an angle against the third plateau member 63. The first quantum dot 65 is disposed at an included-angle location of the first plateau member 61 and the second plateau member 62. The second quantum dot 67 is disposed at an included-angle location of the second plateau member 62 and the third plateau member 63. Likewise, the third quantum dot 69 is disposed at an included-angle location of the third plateau member 63 and the fourth plateau member 64. Again, in one embodiment, the first quantum dot 65, the second quantum dot 67, and the third quantum dot 69 are of approximately spherical shape to provide isotropic and symmetric feature in connection to quantum confinement effect. The first quantum dot 65, the second quantum dot 67, and the third quantum dot 69 may be made of Germanium. Each of the first insulation body 66, the second insulation body 68, and the third insulation body 70 may have an irregular shape with thicker portions and thinner portions but is illusteated as a spherical shell in the drawings. In one embodiment, each insulation body may be made of silicon dioxide with a thickness about 1-2 nm at the thinner portion contacting Si₃N₄, respectively surrounding the first quantum dot 65, the second quantum dot 67, and the third quantum dot 69.

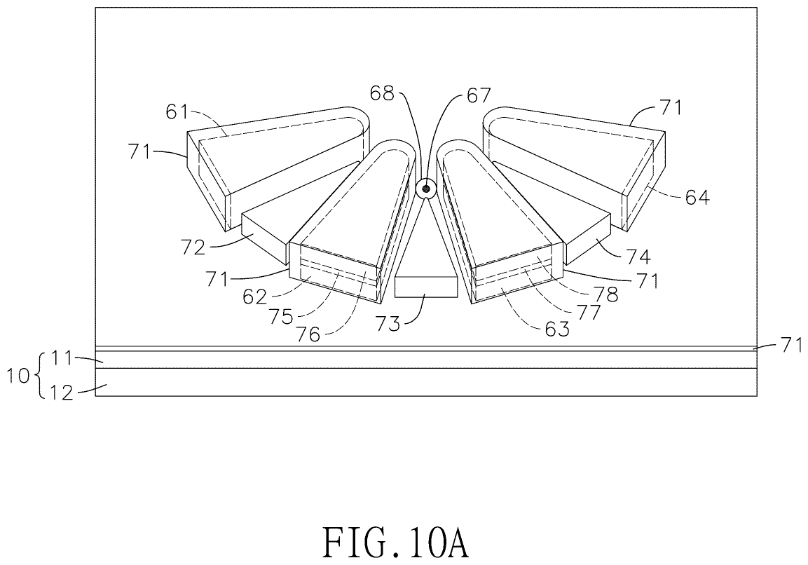

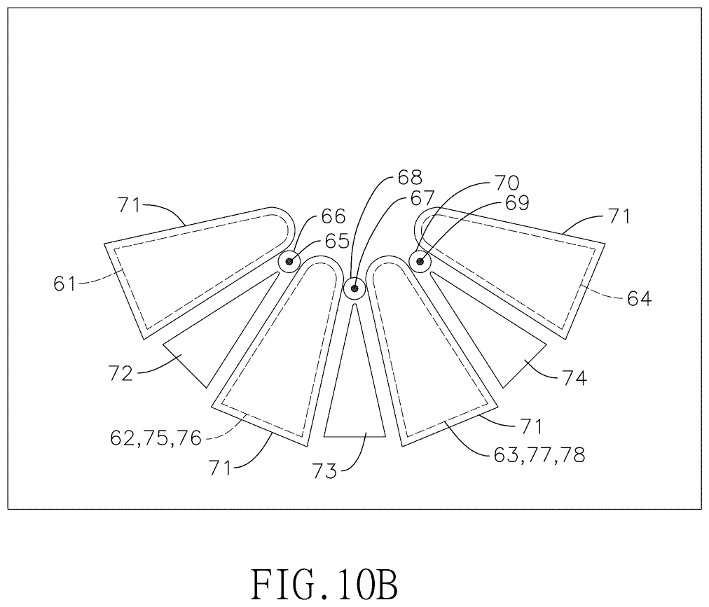

As shown in FIGS. 10A-10B, the double qubit quantum component 60 further includes a first plunger gate 72, a second plunger gate 73, a third plunger gate 74, a first barrier gate 76, and a second barrier gate 78. A first insulating layer 71 is formed on the first plateau member 61, the second plateau member 62, the third plateau member 63, and the fourth plateau member 64. Then, the first plunger gate 72 is disposed, in a self-aligned process, adjacent to the first quantum dot 65 to control its electrostatic potential. The second plunger gate 73 is disposed, in a self-aligned process, adjacent to the second quantum dot 67 to control its electrostatic potential. Likewise, the third plunger gate 74 is disposed, in a self-aligned process, adjacent to the third quantum dot 69 to control its electrostatic potential. As a result, the first plunger gate 72, the second plunger gate 73, and the third plunge gate 74 are electrically insulated from the first plateau member 61, the second plateau member 62, the third plateau member 63, and the fourth plateau member 64. In one embodiment, the first insulation layer 71 is made of Si₃N₄. The first plateau member 61 and the fourth plateau member 64 are conductive and function as reservoirs (respectively a source and a drain) for the double qubit quantum component 60. In one embodiment, the first plateau member 61 and the fourth plateau member 64 are made of P type or N type semiconductor, such as Arsenic-doped or Boron-doped silicon or polysilicon. The second plateau member 62 and the third plateau member 63 are non-conductive and function as coupling barriers (CB) respectively between the first quantum dot 65 and the second quantum dot 67 and between the second quantum dot 67 and the third quantum dot 69. The first barrier gate 76 is disposed, in a self-aligned process, on the second insulating layer 75 which is on top of the second plateau member 62, and between the first plunger gate 72 and the second plunger gate 73. Likewise, the second barrier gate 78 is disposed, in a self-aligned process, on the second insulating layer 77 which is on top of the third plateau member 63, and between the second plunger gate 73 and the third plunger gate 74. In one embodiment, the second plateau member 62 and the third plateau member 63 in the double qubit 60 here have only about half of the thickness of the first and fourth plateau members 61, 64. The first and the second barrier gate 74, 76 are respectively insulated from the second and the third plateau member 62, 63 (functioning as CB) by a second insulating layer 75, 77. In one embodiment, the second and the third plateau members 62, 63 are made of single crystalline silicon; the first and the second barrier gates 76, 78 are made of polysilicon; and the second insulating layer 75, 77 is made of silicon dioxide.

Similar to the qubit 50, the first plateau member 61 in the double qubit 60, for example doped Si or polysilicon, when functioned as a source, is provided with a source voltage V_{S}. The first insulating layer 71, for example Si₃N₄, and the first insulation body 66 surrounding the first quantum dot 65, for example SiO₂, both between the first quantum dot 65 and the first plateau member 61, collectively provide a tunneling capacitor C_{S} and a tunneling resistance R_{S} for the source. Likewise, the fourth plateau member 64, for example doped Si or polysilicon, when functioned as a drain, is provided with a drain voltage V_{D}. The first insulating layer 71, for example Si₃N₄, and the second insulation body 68 surrounding the second quantum dot 67, for example SiO₂, both between the third quantum dot 69 and the fourth plateau member 64, collectively provide a tunneling capacitor C_{D} and a tunneling resistance R_{D} for the drain. The first plunger gate 72 is provided with a first plunger voltage V_{P1} to control confinement barrier of the first quantum dot 65. In other words, the potential of the first quantum dot 65 could be independently adjusted by the first plunger gate 72. The first insulation body 71 surrounding the first quantum dot 65, for example SiO₂, provides a capacitance C_{P1} for the first plunger gate 72. The second plunger gate 73 is provided with a second plunger voltage V_{P2} to control confinement barrier of the second quantum dot 67. In other words, the potential of the second quantum dot 67 could be independently adjusted by the second plunger gate 73. The second insulation body 68 surrounding the second quantum dot 67, for example SiO₂, provides a capacitance C_{P2} for the second plunger gate 73. Likewise, the third plunger gate 74 is provided with a third plunger voltage V_{P3} to control confinement barrier of the third quantum dot 69. In other words, the third quantum dot potential could be independently adjusted by the third plunger gate 73. The third insulation body 70 surrounding the second quantum dot 69, for example SiO₂, provides a capacitance C_{P3} for the third plunger gate 74. The first barrier gate 76 is provided with a first barrier voltage V_{B1} to tune the potential of the first coupling barrier. The second barrier gate 78 is provided with a second barrier voltage V_{B2} to tune the potential of the second coupling barrier. Each of the source, drain, the first plunger gate, the second plunger gate, and the first barrier gate may be independently addressed and provided with different voltages.

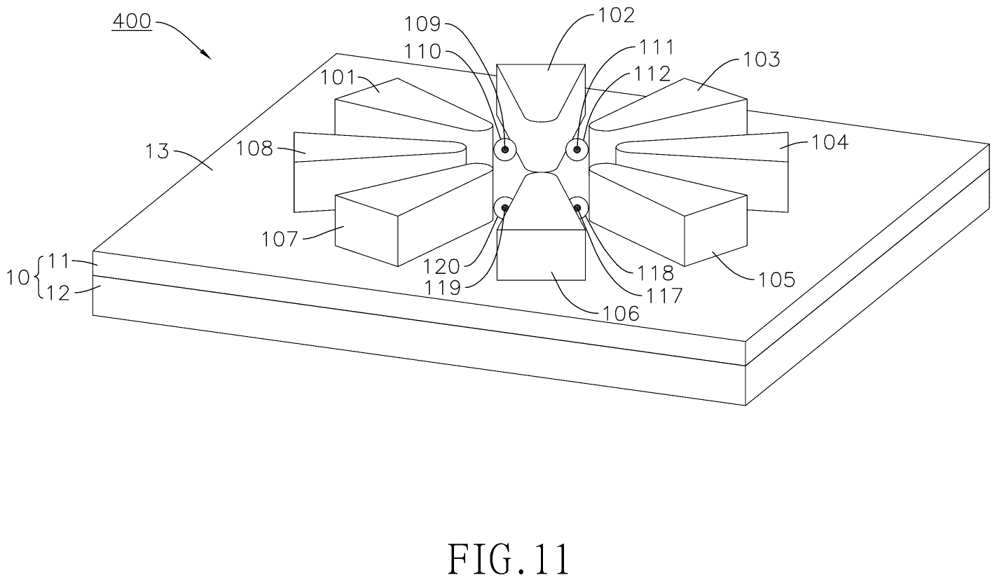

As shown in FIG. 11, a quantum device 400 includes a substrate 10 with an insulation surface 13 and an array of eight plateau members arranged in a circular shape with eight quantum dots each disposed at an included-angle location of two adjacent plateau members. Although there are other possible configurations, in one embodiment, such an array of eight plateau members and eight quantum dots may be configured as four quantum components, namely two SETs/SHTs and two double qubits. The eight quantum dots in a circular-ring arrangement are configured as six quantum dots in two double qubits which are closely-integrated with two quantum dots in two SETs respectively located at the left and right terminals for proximal charge-sensing. The substrate 10 is the same as described before. The first plateau member 101, the second plateau member 102, the third plateau member 103, the fourth plateau member 104, the first quantum dot 109 within the first insulation body 110, and the second quantum dot 111 within the second insulation body 112, and the third quantum dot 113 within the third insulation body 114 constitute the first double qubit. The fourth plateau member 104, the fifth plateau member 105, and the fourth quantum dot 115 within the fourth insulation body 116 constitute the second SET/SHT. The fifth plateau member 105, the sixth plateau member 106, the seventh plateau member 107, the eighth plateau member 108, the fifth quantum dot 117 within the seventh insulation body 118, the sixth quantum dot 119 within the sixth insulation body 120, and the seventh quantum dot 121 within the seventh insulation body 122 constitute the second double qubit. The eighth plateau member 108, the first plateau member 101, and the eighth quantum dot 123 within the eighth insulation body 124 constitute the first SET/SHT. Thus, the first double qubit and the second SET/SHT share the fourth plateau member 104 which functions as a source for both quantum components. The second SET/SHT and the second double qubit share the fifth plateau member 105 which functions as a drain for both quantum components. The second double qubit and the first SET/SHT share the eighth plateau member 108 which functions as a source for both quantum components. The first SET/SHT and the first double qubit share the first plateau member 101 which functions as a drain for both quantum components. In one embodiment, each quantum dot may be of approximately spherical shape to provide isotropic and symmetric feature in connection to quantum confinement effect and made of Germanium. Although each insulation body may have an irregular shape with thicker portions and thinner portions as shown in FIG. 14A, it is illustrated as a spherical shell of silicon dioxide in other drawings. The insulation body may have a thinner portion contacting Si₃N₄ at about 1-2 nm in thickness, respectively surrounding each quantum dot. The plateau members function as a drain or a source are conductive.

As shown in FIGS. 12A-12C, the first double qubit further includes a first plunger gate 126 (P1), a second plunger gate 127 (P2), a third plunger gate 128 (P3), a first barrier gate 135, and a second barrier gate 137. The second SET/SHT further includes a second gate (G2) 129. The second double qubit further includes a fourth plunger gate 130 (P4), the fifth plunger gate 131(P5), the sixth plunger gate 132 (P6), the fourth barrier gate 139 (B4), and the fifth barrier gate 141 (B5). The first SET/SHT further includes a first gate 133 (G1). The arrangements and features of each double qubit here is the same as the double qubit 60 described before and illustrated in FIGS. 9, 10A-10B. The arrangements and features of each SET/SHT is the same as the SET/SHT 20 described before and illustrated in FIGS. 2A-2C. In addition, a common electrode 145, for example made of a poly-Si (or polycide) layer, is located in the center of the array. In one embodiment, the common electrode 145 is connected to a common ground (GND) of the two SETs/SHTs.

As previously described, a quantum device may comprise a very large number of quantum components, including but not limited to a single electron transistor (SET), a single hole transistor (SHT), a single electron transistor invertor (SETI), a single hole transistor inverter (SHTI), a qubit, a double qubit and any combination thereof. An SET or an SHT contains one quantum dot. An SETI, an SHTI, or a qubit contains two quantum dots. A double qubit contains three quantum dots. Regardless of the number of quantum components on a substrate, they may be manufactured all in one time with CMOS compatible approach by employing existing semiconductor manufacturing methods. Thus, millions or even billions of quantum components, including plateau members, quantum dots, and control gates, may be manufactured on a semiconductor wafer. In one embodiment, a quantum device with more than 1,000 quantum dots may be formed during the same processes simultaneously. With the invented manufacturing method, the location, size, and shape of quantum dots as well as the distance between two adjacent quantum dots may be precisely controlled.

A method for making the invented quantum device described above comprises step (a) forming N plateau members on a substrate with an insulation surface wherein N is an integer larger than 1; step (b) forming a first insulating layer on the N multiple plateau members; and step (c) forming N−1 quantum dots. At step (a), each two adjacent plateau members of the N multiple plateau members form an angle. At step (c), each quantum dot is formed within an insulation body and disposed at an included-angle location of each two adjacent plateau members. In addition, a largest distance between any two points of each quantum dot in the quantum device is less than or equal to two times of an exciton Bohr radius of the material of the quantum dot. In one embodiment, each quantum dot is formed in approximately a spherical shape. Each plateau member and each quantum dot may comprise semiconductor materials. Specifically, in one embodiment, each plateau member comprises silicon, each quantum dot comprises germanium, and each insulation body comprises silicon oxide. In the embodiment of germanium quantum dot, a diameter of such a quantum dot is less than approximately 25 nm. In addition, each quantum dot may have a chemical purity of germanium at approximately 100% and/or a single crystallinity. For a quantum device including 2 or more quantum dots, a distance between each two adjacent quantum dots may be less than approximately 20 nm.

The step (c) may further comprise step (c1) forming a semiconductor-alloyed layer on the first insulating layer; step (c2) forming N−1 semiconductor-alloyed islands by etching; and step (c3) oxidizing each semiconductor-alloyed island to form a quantum dot within an insulation body. At step (c2), each semiconductor-alloyed island is disposed, in a self-aligned process, at an included-angle location of each two adjacent plateau members. In one embodiment, thermal oxidation is used to oxidize each semiconductor-alloyed island. In another embodiment, other oxidation methods may be used. The method may further comprise step (d) forming N−1 plunger gates. At step (d), each plunger gate is disposed, in a self-aligned process, adjacent to a quantum dot and between the corresponding two adjacent plateau members.

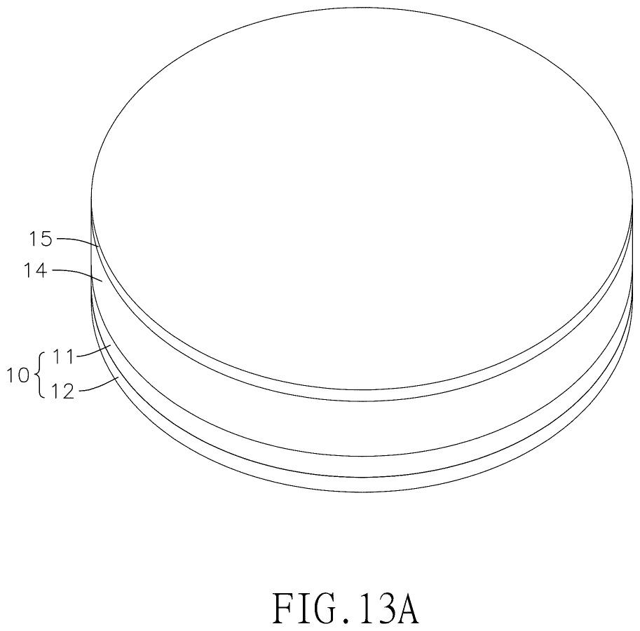

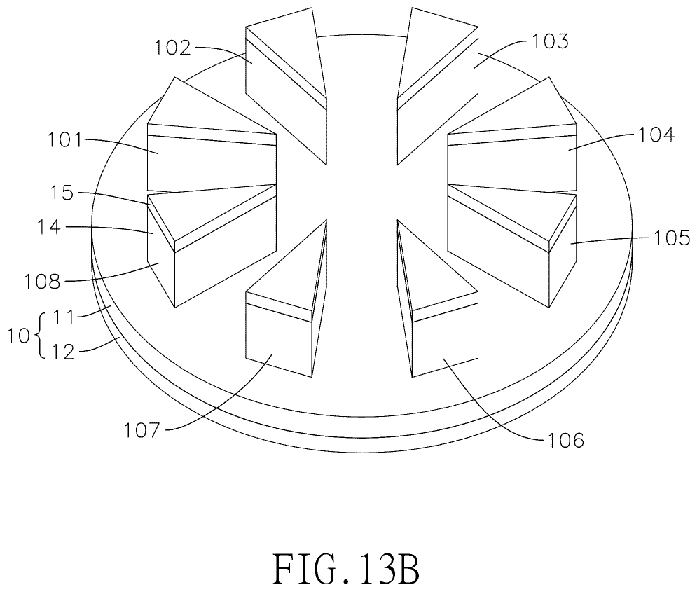

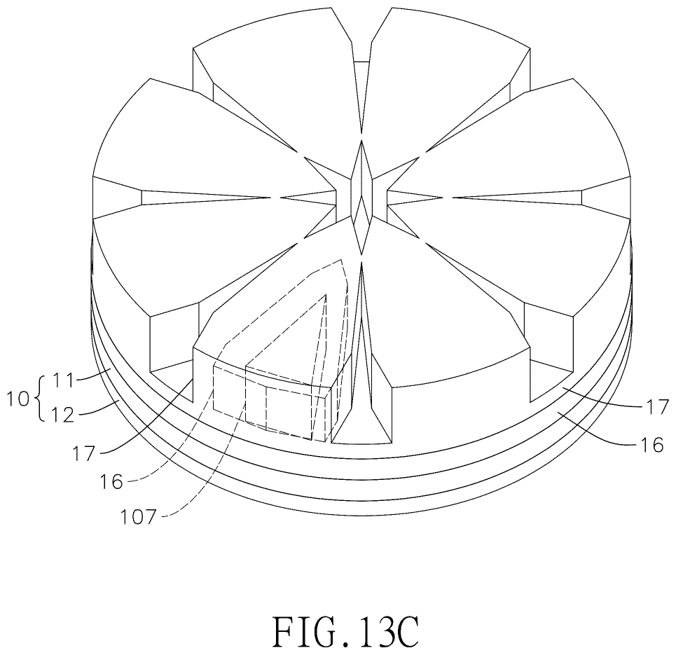

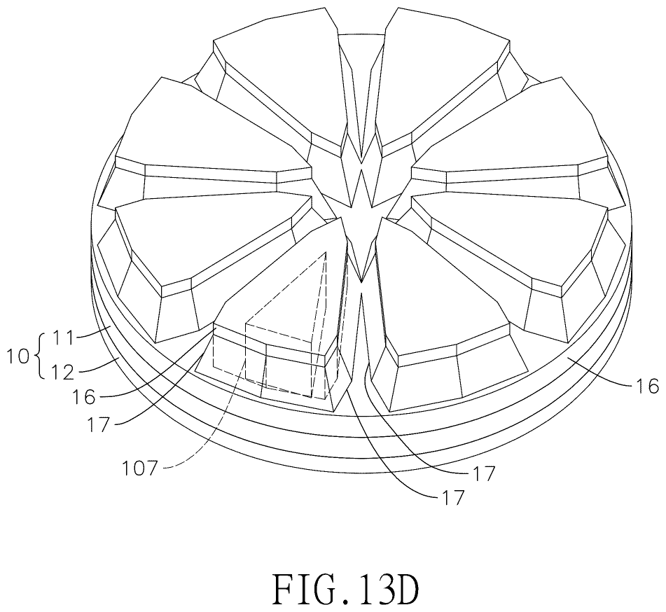

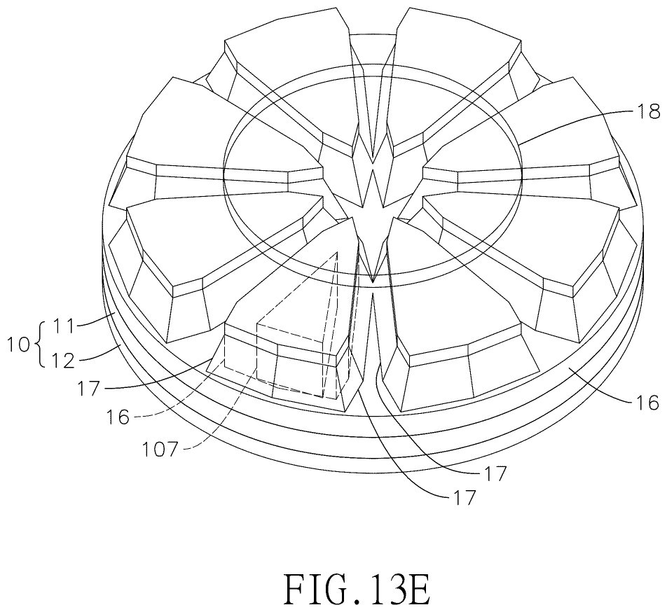

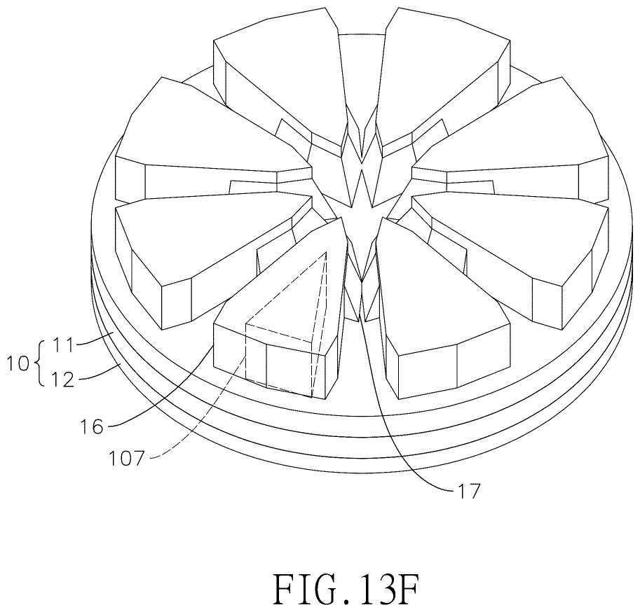

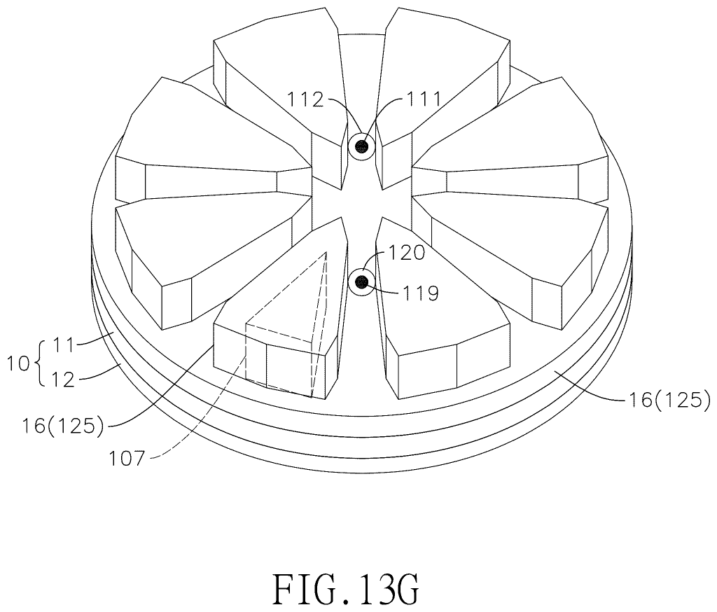

FIGS. 13A-13F demonstrate a method of making a quantum device 400 with two double qubits and two SETs/SHTs functioned as charge sensors for the two double qubits. The quantum device 400 contains eight quantum dots because each double qubit has three quantum dots and each SET has one quantum dot. As shown in FIG. 13A, a semiconductor layer 14 is formed on a substrate 10 with an insulation surface. In one embodiment, a silicon-on-insulator (SOI) wafer is provided which includes a single crystalline silicon layer 14 with a thickness of about 100 nm formed on a substrate 10 which further comprises a silicon dioxide layer 11 with a thickness of about 400 nm on a silicon layer 12. An insulation layer 15 is formed on the single crystalline silicon layer 14 to function as a hard-mask for forming eight plateau members. In one embodiment, the insulation layer 15 is a Si₃N₄ layer with a thickness of about 25 nm deposited by using low-pressure chemical vapor deposition (LPCVD). The electron-beam lithography (EBL) is used to pattern the insulation layer 15 for the eight plateau members arranged in a circular shape. Then, an etching process using SF₆/C₄F₈ plasma is performed on the single crystalline silicon layer 14 using the patterned mask layer 15 as a mask to form the eight plateau members as shown in FIG. 13B. The silicon dioxide layer 11 is exposed after the remaining part of the single crystalline silicon layer 14 is removed.

Next, as shown in FIG. 13C, a first insulating layer 16 and then a semiconductor-alloyed layer 17 are sequentially formed on the eight plateau members 101-108. In one embodiment, a 10 nm-thick Si₃N₄ layer (the first insulating layer 16) and a 20-25 nm-thick poly-Si_{0.85}Ge_{0.15} layer (the semiconductor-alloyed layer 17) are sequentially deposited using LPCVD for conformal encapsulation over the eight plateau members as well as the silicon dioxide layer 11 of the substrate 10. Then, a direct etch-back process is conducted to remove the semiconductor-alloyed layer 17 on top of the first insulating layer 16 of the plateau members to symmetrically form spacer strips of the semiconductor-alloyed material at each sidewall of the plateau members covered by the first insulating layer 16 as shown in FIG. 13D. In one embodiment, a direct etch-back process using SF₆/C₄F₈ plasma is conducted to remove the poly-silicon germanium (poly-Si_{0.85}Ge_{0.15}) on top of the Si₃N₄ layer of the plateau members to symmetrically produce spacer stripes of poly-Si_{0.85}Ge_{0.15} with width/height of about 20-30/10-30 nm The size of the spacer stripes may be adjusted by the etch-back process time.

As shown in FIG. 13E, lithographic patterning by a mask (photoresist layer 18) shadows the central regions of the designed fanout plateau members 101-108. Then, as shown in FIG. 13F, etching is conducted to form spacer islands of semiconductor-alloyed materials between each two adjacent plateau members covered by the first insulating layer 16. In one embodiment, electron-beam lithography (EBL) is used again to shadow the central regions of the fanout plateau members and then an etching process using SF₆/C₄F₈ plasma is performed to define the lengths of the poly-Si_{0.85}Ge_{0.15} spacer islands at each included angle location of two adjacent plateau members by removing other poly-Si_{0.85}Ge_{0.15} materials of the spacer stripes. Subsequently, an oxidation process is performed to condense quantum dots within an insulation body at the included angle location of each two adjacent plateau members covered by the first insulating layer 16, as shown in FIG. 13G. In one embodiment, a thermal oxidation at about 900° C. for 25-40 min in an H₂O ambient is performed to convert these poly-Si_{0.85}Ge_{0.15} spacer islands to Ge quantum dots with cladding silicon dioxide layers at the included angle location of each two adjacent Si plateau members covered by a Si₃N₄ layer.

The location of a quantum dot may be precisely controlled. Each quantum dot is produced at the included angle location of two adjacent plateau members. Thus, by designing the layout of the plateau members and the thickness of the first insulating layer 16, the location of each quantum dot may be decided. Moreover, the location of a quantum dot may be also adjusted by the process time of thermal oxidation. In one embodiment, as the thermal oxidation time increases, the Ge quantum dots further penetrate into the silicon nitride (Si₃N₄) layer 16 covering the plateau members. The size of the quantum dots is tunable because it is determined by the geometrical sizes of the semiconductor-alloyed spacer islands, which are varied by controlling the process times for deposition, etch back, and lithography. In one embodiment, owing to the Ge condensation and ripening during the poly-SiGe oxidation, the resulting Ge quantum dot size is smaller than the size of the poly-SiGe spacer island. The process-controlled size of Ge quantum dots may range from 7 to 25 nm. With advanced semiconductor manufacturing technologies, the size or diameter of a quantum dot may be shrunk to 5 nm, 3 nm, 2 nm, or even 1 nm. In addition, a distance between two adjacent quantum dots separated by a plateau member covered by a first insulating layer may be precisely controlled by the thickness of the plateau member and the first insulating layer as well as the process time of thermal oxidation. In one embodiment, the depth of penetration of Ge quantum dots into silicon nitride layer is enhanced by increasing the thermal oxidation time. In one embodiment, the distance between two adjacent quantum dots may range from 10 to 20 nm. With advanced semiconductor manufacturing technologies, the distance between two adjacent quantum dots may be shrunk to 7 nm, 5 nm, 3 nm, or even smaller. As mentioned before, each quantum dot is surrounded by an insulation body, such as silicon dioxide, which may have an irregular shape with thicker portions and thinner portions. The portions of the insulation body contacting the Si₃N₄ (the first insulating layer) is thinner, for example about 1-2 nm. Other portions of the insulation body are usually thicker. However, each insulation body is illustrated by a spherical shell covering the quantum dot in the drawings.

After the formation of plateau members, quantum dots, and the first insulating layer, plunger gates, barrier gates, common gate, and reservoirs (sources or drains) of the quantum components are formed. As shown in FIGS. 2B, 8B, 14A-14F, among others, plunger gates, barrier gates, and reservoirs of two quantum components, for example a SET/SHT 20 and a qubit 50, are formed on the insulation surface 13 of the substrate 10, for example a silicon dioxide layer 11. FIGS. 2B and 8B respectively illustrate a top view of an SET/SHT 20 and a qubit 50 after the formation of plunger gates, barrier gates, and reservoirs. FIGS. 14A-14F respectively illustrate a cross sectional view of a qubit 50 and a SET/SHT 20 from the AA′ direction of FIGS. 2B and 8B. As shown in FIGS. 14A, a layer of photoresist 19 is formed to cover these two quantum components and the surface 13 of the substrate 10. AA′ direction is an arc connecting quantum dots in a circular-ring arrangement. After lithography and removal of the exposed or non-exposed portion of photoresist layer, the second plateau member 32 of the qubit 50, which will serve as a coupling barrier (CB), is revealed. Next, as shown in FIG. 14B, the first insulating layer 38 (16 in FIG. 13G) on top of the second plateau member 32 and a top portion of the second plateau member 32 are sequentially removed by appropriate etchants. In one embodiment, after electron beam lithography (EBL) patterning, the top portion of first insulating layer 38 made of Si₃N₄ and about top half portion (50 nm out of 100 nm thickness) of the second plateau member 32 made of single crystalline silicon are sequentially removed using CHF₃ plasma and SF₆/C₄F₈ plasma, respectively. The Si₃N₄ layer 38 on the side of the second plateau member 32 is mostly intact and thus has a thickness higher than that of the remaining second plateau member 32. The quantum component 20 without a coupling barrier, for example a SET, is completely covered by the photoresist layer and nothing is removed as shown in FIGS. 14A & 14B.

As shown in FIGS. 14C, a second insulating layer 53 is formed on top of the remaining second plateau member 32. In one embodiment, a subsequent thermal oxidation process grows a 5 nm-thick SiO₂ layer (the second insulating layer 53) on top of the remaining second plateau member 32. Next, as shown in FIGS. 14D & 14E, a conductive layer 1400 is formed on the surface of these two quantum components and then directly etched back to simultaneously form, in a self-aligned process, the plunger gates 28, 51, 52, the barrier gate 54, and the common gate (145 in FIGS. 12A &12B; not shown here) at the center of the array. In one embodiment, combined processes of deposition and direct etch-back of 100 nm-thick poly-Si layer simultaneously form plunger gates 28, 51, 52 on top of the Ge quantum dots capped by SiO₂ and barrier gates 54 over the 5 nm-thick SiO₂ on top of the remaining second plateau member 32 in a self-aligned approach. Finally, as shown in FIG. 14F, the plunger gates 51, 52, the barrier gate 54, and the first and the third plateau members 31, 33 (served as reservoirs) of the qubit 50, and the plunger gate 28, and the plateau members 21, 22 (served as reservoirs) are converted to metallic electrodes by using the self-aligned silicidation processes. The same numbers are used to represent the plunger gates, the barrier gates, and the reservoirs before and after the silicidation processes. These silicides (metallic electrodes) have fairly low resistivity and good high-temperature-stability. The self-aligned-silicidation process is widely used in integrated circuits to reduce polysilicon gate resistance and source/drain contact resistance. One of the advantages is that the silicide is selectively formed on the polysilicon gate and source/drain diffused regions, while oxide or nitride can serve as a reaction mask. Thus, the process is simple because no additional mask is needed. In one embodiment, the poly-Si plunger gates 51, 52, poly-Si barrier gate 54, and the single crystalline Si first and the third plateau members 31, 33 (serving as source and drain) of the qubit 50 could be converted to metallic electrodes of NiSi by using the self-aligned silicidation processes. In the above described manufacturing process, EBL ay be conducted using Raith VOYAGER electron-beam lithography system (Raith GmbH, Dortmund, Germany) and etching may be conducted using Oxford DSiE plasma etcher (Oxford Instruments plc, Abingdon, UK).

The quantum devices and the method of making the same described above has one or more of the following ten advantages.

1. The quantum devices, including the quantum components and the quantum dots are operable at 4 K and above, such as at 77 K and even at 300 K. A quantum device includes at least one quantum component which may be one of a single electron transistor (SET), a single hole transistor (SHT), a single electron transistor invertor, a single hole transistor inverter, a qubit, a double qubit, and any combination thereof. A quantum component is operable at a certain temperature when information stored in the quantum dot may be measured under the noises generated at such a temperature. The properties of a quantum dot may be determined at least by its material, size, shape, strain, purity, crystallinity, and inter-quantum dot spacing (for a quantum component including two or more quantum dots). In general, the smaller the size of the quantum dot is, the higher the operating temperature of the quantum component is. When a largest distance between any two points of the quantum dot in the quantum component is less than or equal to two times of an exciton Bohr radius of the material of the quantum dot, such quantum dot begins to demonstrate quantum confinement effect. In one embodiment, the quantum dot is made of Germanium whose exciton Bohr radius is about 24.9 nm. The Ge quantum dot, at approximately spherical shape with a diameter around 11 nm, surrounded by a thin silicon dioxide shell, is operable at 77K. Similarly, such a Ge quantum dot is operable at 300 K if its diameter is respectively around or less than 7 nm.

2. The quantum dot is isotropic and symmetric with respect to quantum confinement effect when it is at approximately spherical shape. In one embodiment, The Ge quantum dot is created by selective oxidation process of poly-Si₁₋ₓGeₓ lithographically-patterned structures (spacer islands) located at each included-angle location of two adjacent plateau members with Si₃N₄ in proximity. During the thermal oxidation, the Ge quantum dot is formed within a thin silicon dioxide shell. The Ge quantum dot becomes approximately a sphere shape when it moves toward and in contact with the Si₃N₄ layer outside the plateau members.

3. The location of the quantum dot may be precisely tuned for intended design and function. Several methods may be used to control the location of the quantum dot. First, since the quantum dot will be produced between two adjacent plateau members disposed at a specific angle, the layout of the quantum device, which includes the location of the plateau members will decide the approximate location of the quantum dot. Moreover, the location of the quantum dot may be also adjusted by the process time of thermal oxidation. In one embodiment, as the thermal oxidation time increases, the Ge quantum dot penetrates further into the silicon nitride layer outside the plateau members.

4. The number of quantum dots formed in a quantum device is scalable and unlimited. In one embodiment, the overall number of Ge quantum dots scales with the fanout number of the plateau members, such as Si, via positioning a single Ge quantum dots at each included-angle location. The smaller the angle between two adjacent plateau members is, the larger number of quantum dots may be formed in the quantum device.

5. The diameter (size) of quantum dots is tunable. The quantum dot diameter (size) is determined by the geometrical sizes of the semiconductor-alloyed islands, for example SiGe spacer islands, which are varied by controlling the process times for deposition, etch back, and EBL. Owing to the Ge condensation and ripening during the SiGe oxidation, the resulting Ge quantum dot size is, by definition, smaller than the size of the poly-SiGe spacer island. In one embodiment, a tunable range of process-controlled size of the Ge quantum dot is about 7-20 nm.

6. The distance between two adjacent quantum dots is tunable at least by the process time of thermal oxidation. In one embodiment, the depth of penetration of quantum dots into silicon nitride layer is enhanced by increasing the thermal oxidation time. In other words, the longer the thermal oxidation is performed, the shorter the distance between two adjacent quantum dots is.

7. Plunger gates and barrier gates may be formed by a self-aligned process. The plunger gates and barrier gates may be formed by deposition of conductive materials, such as polysilicon, and etch-back without additional photolithography.

8. The quantum device may be manufactured by CMOS compatible fabrication approach, such as photolithography, deposition, and etching. As a result, the quantum device may be integrated with CMOS components, such as transistors, capacitors, and resistors.

9. Each quantum component is independently addressable and electrically tunable by its reservoirs (source or drain), plunger gates, and/or barrier gates to control the electrostatic potential of quantum dots, tunneling barriers/coupling barriers, etc. by independently providing these reservoirs and gates separate voltages.

10. The quantum dots in a quantum device may be reconfigurable into different types of quantum components, such as SETs/SHTs and qubits, based on an intended use. For example, the quantum device 400 is configured to form two SETs/SHTs and two double quits. Both SETs/SHTs and qubits have plunger gates but only qubits have barrier gates. On one embodiment, each quantum dot is disposed at the included angle location of two adjacent Si plateau members and one poly-Si plunger gate is in close proximity to capacitively modulate the electrostatic potential of the quantum dot. The Si plateau members may serve as reservoirs (source or drain) or barriers depending on the conductivity being high or low (that is, the Si plateau member is heavily doped or not). If the Si plateau members are heavily doped, then the Si plateau members serve as reservoirs for charge injection (source electrode) and charge collection (drain electrode). If the Si plateau member are undoped (close to the intrinsic Si), the Si plateau member can serve as the inter-quantum dot barrier for the charge wave coupling.

The following publications are incorporated herein by reference at their entireties.
1. I-Hsiang Wang, Po-Yu Hong, Kang-Ping Peng, Horng-Chih Lin, Thomas George, and Pei-Wen Li, 2021, “Germanium quantum-dot array with self-aligned electrodes for quantum electronic devices,” Nanomaterials, vol. 11, 2743. DOI: 10.3390/nano11102743
2. I-Hsiang Wang, Ting Tsai, Rong-Cun Pan, Po-Yu Hong, M. T. Kuo, I. H. Chen, Thomas George, H. C. Lin, and Pei-Wen Li, “Reconfigurable Germanium Quantum-Dot Arrays for CMOS Integratable Quantum Electronic Devices” VLSI Tech. Dig., JFS5-6, pp. 1-2, June 2021 (Kyoto, Japan)

The foregoing description of embodiments is provided to enable any person skilled in the art to make and use the subject matter. Various modifications to these embodiments will be readily apparent to those skilled in the art, and the novel principles and subject matter disclosed herein may be applied to other embodiments without the use of the innovative faculty. The claimed subject matter set forth in the claims is not intended to be limited to the embodiments shown herein but is to be accorded the widest scope consistent with the principles and novel features disclosed herein. It is contemplated that additional embodiments are within the spirit and true scope of the disclosed subject matter. Thus, it is intended that the present invention covers modifications and variations that come within the scope of the appended claims and their equivalents.

What is claimed is:

1. A quantum device, comprising:
a substrate with an insulation surface; and
at least one quantum component disposed on the insulation surface of the substrate comprising:
a first plateau member;
a second plateau member separated from the first plateau member and disposed at an angle against the first plateau member;
a first quantum dot formed within a first insulation body and disposed at an included-angle location of the first plateau member and the second plateau member; and
wherein a largest distance between any two points of the first quantum dot in the quantum component is less than or equal to two times of an exciton Bohr radius of the material of the first quantum dot.

2. The quantum device of claim 1, wherein the at least one quantum component is a single electron transistor (SET) or a single hole transistor (SHT) and further comprises:
a first insulating layer formed on the first plateau member and the second plateau member;
a first plunger gate disposed, in a self-aligned process, adjacent to the first quantum dot and between the first plateau member and the second plateau member;
wherein the first quantum dot is formed in approximately a spherical shape; and
wherein the first plateau member, the second plateau member, and the first plunger gate are electrically conductive.

3. The quantum device of claim 2, wherein the first plateau member, the second plateau member, and the first quantum dot comprise semiconductor materials.

4. The quantum device of claim 3, wherein the first plateau member and the second plateau member comprise silicon, the first quantum dot comprises germanium, and the first insulation body comprises silicon dioxide.

5. The quantum device of claim 4, wherein a diameter of the first quantum dot is less than approximately 25 nm.

6. The quantum device of claim 1, wherein the at least one quantum component is a single electron transistor invertor or a single hole transistor inverter, and further comprises:
a third plateau member separated from the first plateau member and the second plateau member, and disposed at an angle against the second plateau member;
a second quantum dot formed within a second insulation body and disposed at an included-angle location of the second plateau member and the third plateau member;
a first insulating layer formed on the first plateau member, the second plateau member, and the third plateau member;
a first plunger gate disposed, in a self-aligned process, adjacent to the first quantum dot and between the first plateau member and the second plateau member;
a second plunger gate disposed, in a self-aligned process, adjacent to the second quantum dot and between the second plateau member and the third plateau member;
wherein each of the first quantum dot and the second quantum dot is formed in approximately a spherical shape; and
wherein the first plateau member, the second plateau member, and the third plateau member are electrically conductive.

7. The quantum device of claim 6, wherein the first plateau member, the second plateau member, the third plateau member, the first quantum dot, and the second quantum dot comprise semiconductor materials.

8. The quantum device of claim 7, wherein each of the first plateau member, the second plateau member, and the third plateau member comprises silicon, each of the first quantum dot and the second quantum dot comprises germanium, and each of the first insulation body and the second insulation body comprises silicon dioxide.

9. The quantum device of claim 8, wherein a diameter of each of the first quantum dot and the second quantum dot is less than approximately 25 nm.

10. The quantum device of claim 8, wherein a distance between the first quantum dot and the second quantum dot is less than approximately 20 nm.

11. The quantum device of claim 1, wherein the at least one quantum component is a qubit and further comprises:
a third plateau member separated from the first plateau member and the second plateau member, and disposed at an angle against the second plateau member;
a second quantum dot formed within a second insulation body and disposed at an included-angle location of the second plateau member and the third plateau member, and
wherein each of the first quantum dot and the second quantum dot is formed in approximately a spherical shape.

12. The quantum device of claim 11, wherein the qubit further comprises:
a first plunger gate disposed, in a self-aligned process, adjacent to the first quantum dot and between the first plateau member and the second plateau member;
a second plunger gate disposed, in a self-aligned process, adjacent to the second quantum dot and between the second plateau member and the third plateau member;
a first barrier gate disposed adjacent to the second plateau member and between the first plunger gate and the second plunger gate;
a first insulating layer formed on the first plateau member, the second plateau member and the third plateau member; and
wherein the first plateau member and the third plateau member are electrically conductive, and the second plateau member is not electrically conductive.

13. The quantum device of claim 12, wherein the first plateau member and the third plateau member are respectively a source and a drain of the qubit.

14. The quantum device of claim 12, wherein the first plateau member, the second plateau member, the third plateau member, the first quantum dot, and the second quantum dot comprise semiconductor materials.

15. The quantum device of claim 14, wherein each of the first plateau member, the second plateau member, and the third plateau member comprises silicon, each of the first quantum dot and the second quantum dot comprises germanium, and each of the first insulation body and the second insulation body comprises silicon dioxide.

16. The quantum device of claim 15, wherein a diameter of each of the first quantum dot and the second quantum dot is less than approximately 25 nm.

17. The quantum device of claim 16, wherein a distance between the first quantum dot and the second quantum dot is less than 20 nm.

18. The quantum device of claim 1, wherein the at least one quantum component is a double qubit and further comprises:
a third plateau member separated from the first plateau member and the second plateau member, and disposed at an angle against the second plateau member;
a second quantum dot formed within a second insulation body and disposed at an included-angle location of the second plateau member and the third plateau member;
a fourth plateau member separated from the first plateau member, the second plateau member and the third plateau member, and disposed at an angle against the third plateau member;
a third quantum dot formed within a third insulation body and disposed at an included-angle location of the third plateau member and the fourth plateau member; and
wherein each of the first quantum dot, the second quantum dot, and the third quantum dot is formed in approximately a spherical shape.

19. The quantum device of claim 18, wherein the double qubit further comprises:
a first plunger gate disposed, in a self-aligned process, adjacent to the first quantum dot and between the first plateau member and the second plateau member;
a second plunger gate disposed, in a self-aligned process, adjacent to the second quantum dot and between the second plateau member and the third plateau member;
a third plunger gate disposed, in a self-aligned process, adjacent to the third quantum dot and between the third plateau member and the fourth plateau member;
a first barrier gate disposed adjacent to the second plateau member and between the first plunger gate and the second plunger gate;
a second barrier gate disposed adjacent to the third plateau member and between the second plunger gate and the third plunger gate;
a first insulating layer formed on the first plateau member, the second plateau member, the third plateau member, and the fourth plateau member; and
wherein the first plateau member and the fourth plateau member are electrically conductive, and the second plateau member and the third plateau member are not electrically conductive.

20. The quantum device of claim 19, wherein the first plateau member, the second plateau member, the third plateau member, the fourth plateau member, the first quantum dot, the second quantum dot, and the third quantum dot comprise semiconductor materials.

21. The quantum device of claim 20, wherein each of the first plateau member, the second plateau member, the third plateau member, and the fourth plateau member comprises silicon, each of the first quantum dot, the second quantum dot, and the third quantum dot comprises germanium, and each of the first insulation body, the second insulation body, and the third insulation body comprises silicon dioxide.

22. The quantum device of claim 21, wherein a diameter of each of the first quantum dot, the second quantum dot, and the third quantum dot is less than approximately 25 nm.

23. The quantum device of claim 20, wherein a distance between each two adjacent quantum dots is less than 20 nm.

24. A method for making a quantum device, comprising:
(a) forming N plateau members on a substrate with an insulation surface wherein N is an integer larger than 1 and each two adjacent plateau members of the N multiple plateau members form an angle;
(b) forming a first insulating layer on the N multiple plateau members;
(c) forming N−1 quantum dots, each quantum dot formed within an insulation body and disposed at an included-angle location of each two adjacent plateau members;
wherein a largest distance between any two points of each quantum dot in the quantum device is less than or equal to two times of an exciton Bohr radius of the material of the quantum dot.

25. The method of claim 24, wherein step (c) comprises
(c1) forming a semiconductor-alloyed layer on the first insulating layer;
(c2) forming N−1 semiconductor-alloyed islands by etching, each semiconductor-alloyed island disposed, in a self-aligned process, at an included-angle location of each two adjacent plateau members; and
(c3) oxidizing each semiconductor-alloyed island to form a quantum dot within an insulation body.

26. The method of claim 25, wherein thermal oxidation is used to oxidize each semiconductor-alloyed island.

27. The method of claim 24, further comprising:
(d) forming N−1 plunger gates, each plunger gate disposed, in a self-aligned process, adjacent to a quantum dot and between the corresponding two adjacent plateau members.

28. The method of claim 24, wherein each quantum dot is formed in approximately a spherical shape.

29. The method of claim 28, wherein each plateau member and each quantum dot comprise semiconductor materials.

30. The method of claim 29, wherein each plateau member comprises silicon, each quantum dot comprises germanium, and each insulation body comprises silicon oxide.

31. The method of claim 30, wherein each quantum dot has a diameter less than approximately 20 nm.

32. The method of claim 30, wherein each quantum dot has a chemical purity of germanium at approximately 100%.

33. The method of claim 30, wherein each quantum dot has a single crystallinity.

34. The method of claim 30, wherein a distance between each two adjacent quantum dots is less than approximately 20 nm.

35. The method of claim 24, wherein more than 1,000 quantum dots are formed on the substrate simultaneously.

36. A quantum device, comprising:
a substrate with an insulation surface;
at least one quantum component disposed on the insulation surface of the substrate comprising:
multiple plateau members, each of which is disposed at an angle against an adjacent plateau member;
at least one quantum dot, each of which is formed within an insulation body and disposed at an included-angle location of two adjacent plateau members of the multiple plateau members;
wherein the at least one quantum component is operable at a temperature above 4 K.

37. The quantum device of claim 36, wherein the at least one quantum component is operable at a temperature above 77 K.

38. The quantum device of claim 36, wherein the at least one quantum dot has approximately a spherical shape.

39. The quantum device of claim 38, wherein the at least one quantum dot has a diameter less than an exciton Bohr radius of the material of the quantum dot.

40. The quantum device of claim 38, wherein the at least one quantum dot comprises germanium.

41. The quantum device of claim 39, wherein the at least one quantum dot has a diameter less than 25 nm.

42. The quantum device of claim 40, wherein the at least one quantum dot comprises approximately 100% germanium.

43. The quantum device of claim 36, wherein the at least one quantum dot is formed by thermal oxidation of semiconductor-alloyed material.

44. The quantum device of claim 36, wherein the at least one quantum component further comprises a plunger gate formed by a self-aligned process for each quantum dot.

45. The quantum device of claim 36, wherein each quantum component is independently addressable.

46. The quantum device of claim 40, wherein a distance between two adjacent quantum dots of the multiple quantum dots is less than 20 nm.

47. The quantum device of claim 36, wherein the at least one quantum component comprises at least one of a single electron transistor (SET), a single hole transistor (SHT), a single electron transistor invertor (SETI), a single hole transistor inverter (SHTI), a qubit, and a double qubit.

48. The quantum device of claim 47, wherein the at least one quantum component comprises an SET/SHT and a qubit/double qubit, and the SET/SHT is disposed in close proximity to the qubit/double qubit for sensing potential variations induced by charge movement between two quantum dots of the qubit/double qubit.
